(19) United States
(12) Patent Application Publication
(10) Pub. No.: US 2025/0048699 A1
(43) Pub. Date: Feb. 6, 2025

(54) SEMICONDUCTOR DEVICE AND METHOD OF FABRICATING THE SAME

(71) Applicant: Samsung Electronics Co., Ltd., Suwon-si (KR)

(72) Inventors: Ki Hwan KIM, Suwon-si (KR); Unki KIM, Suwon-si (KR); Chanyoung KIM, Suwon-si (KR); Jeongho YOO, Suwon-si (KR); Ingyu JANG, Suwon-si (KR); Sujin JUNG, Suwon-si (KR)

(21) Appl. No.: 18/607,960

(22) Filed: Mar. 18, 2024

(30) Foreign Application Priority Data
Aug. 1, 2023 (KR) 10-2023-0100508

(51) Int. Cl. H01L 29/10; H01L 29/08; H01L 29/423

(52) U.S. Cl. CPC H01L 29/1033; H01L 29/0847; H01L 29/42364

(57) ABSTRACT

A semiconductor device includes a substrate including an active pattern, a channel pattern and a source/drain pattern on the active pattern wherein the channel pattern includes semiconductor patterns vertically stacked and spaced apart from each other, the plurality of semiconductor patterns including a first semiconductor pattern and a neighboring second semiconductor pattern, and a gate electrode on the semiconductor patterns. The gate electrode includes an inner electrode between the first and second semiconductor patterns. The source/drain pattern includes a buffer layer and a main layer on the buffer layer. An indent region is defined in a vertical cross section of the device by the main layer, the first and second semiconductor patterns, and the inner electrode. The buffer layer is in the indent region. The buffer layer does not extend onto sidewalls of the first and second semiconductor patterns.

### CROSS-REFERENCE TO RELATED APPLICATION

This U.S. nonprovisional application claims priority under 35 U.S.C § 119 to Korean Patent Application No. 10-2023-0100508 filed on Aug. 1, 2023 in the Korean Intellectual Property Office, the disclosure of which is hereby incorporated by reference in its entirety.

### BACKGROUND

The present inventive concepts relate to a semiconductor device and a method of fabricating the same, and more particularly, to a semiconductor device including a field effect transistor and a method of fabricating the same.

A semiconductor device includes an integrated circuit including metal oxide semiconductor field effect transistors (MOSFETs). As sizes and design rules of semiconductor devices are gradually decreased, sizes of the MOSFETs are also increasingly scaled down. The scale down of MOSFETs may deteriorate operating characteristics of the semiconductor device. Accordingly, various studies have been conducted to develop methods of fabricating semiconductor devices having superior performance while overcoming limitations arising with high integration of the semiconductor devices.

### SUMMARY

Some embodiments of the present inventive concepts provide a semiconductor device having improved electrical properties and increased reliability.

Some embodiments of the present inventive concepts provide a method of fabricating a semiconductor device having improved electrical properties and increased reliability.

According to some embodiments of the present inventive concepts, a semiconductor device may include a substrate including an active pattern; a channel pattern and a source/drain pattern on the active pattern, wherein the channel pattern includes a plurality of semiconductor patterns vertically stacked and spaced apart from each other, the plurality of semiconductor patterns including a first semiconductor pattern and a second semiconductor pattern neighboring the first semiconductor pattern; and a gate electrode on the plurality of semiconductor patterns, wherein the gate electrode includes an inner electrode between the first semiconductor pattern and the second semiconductor pattern, wherein the source/drain pattern includes a buffer layer and a main layer on the buffer layer, wherein an indent region is defined in a vertical cross section of the semiconductor device by the main layer, the first semiconductor pattern, the second semiconductor pattern, and the inner electrode, wherein the buffer layer is in the indent region, and wherein the buffer layer does not extend onto sidewalls of the first semiconductor pattern and the second semiconductor pattern.

According to some embodiments of the present inventive concepts, a semiconductor device may include a substrate including an active pattern; a channel pattern and a source/drain pattern on the active pattern, wherein the channel pattern includes a plurality of semiconductor patterns vertically stacked and spaced apart from each other, the plurality of semiconductor patterns including a first semiconductor pattern and a second semiconductor pattern neighboring the first semiconductor pattern; and a gate electrode on the plurality of semiconductor patterns, wherein the gate electrode includes an inner electrode between the first semiconductor pattern and the second semiconductor pattern, wherein the source/drain pattern includes a buffer layer and a main layer on the buffer layer, wherein the buffer layer is between the main layer and the inner electrode, wherein the buffer layer has a first sidewall that faces the inner electrode, wherein the first semiconductor pattern has a second sidewall in contact with the main layer, and wherein a curvature of the first sidewall is less than a curvature of the second sidewall.

According to some embodiments of the present inventive concepts, a semiconductor device may include a substrate including an NMOSFET region; an active pattern on the NMOSFET region; a channel pattern and a source/drain pattern on the active pattern, wherein the channel pattern includes a plurality of semiconductor patterns stacked and spaced apart from each other, the plurality of semiconductor patterns including a first semiconductor pattern and a second semiconductor pattern neighboring the first semiconductor pattern; a gate electrode on the channel pattern, wherein the gate electrode includes: an inner electrode between the first semiconductor pattern and the second semiconductor pattern, and an outer electrode on an uppermost semiconductor pattern among the plurality of semiconductor patterns; a gate dielectric layer between the inner electrode and the source/drain pattern; a gate spacer on a sidewall of the outer electrode; a gate capping pattern on a top surface of the outer electrode; an interlayer dielectric layer on the gate capping pattern and the source/drain pattern; a gate contact that penetrates the interlayer dielectric layer and the gate capping pattern and is electrically connected with the gate electrode; an active contact that penetrates the interlayer dielectric layer and is electrically connected with the source/drain pattern; and a first metal layer on the interlayer dielectric layer, wherein the first metal layer includes a plurality of first wiring lines that are electrically connected to the gate contact and the active contact, wherein the gate dielectric layer has a first sidewall in contact with the source/drain pattern, wherein the first semiconductor pattern has a second sidewall in contact with the source/drain pattern, and wherein a curvature of the first sidewall is less than a curvature of the second sidewall.

### BRIEF DESCRIPTION OF DRAWINGS

FIGS. 1, 2, and 3 illustrate conceptual views showing logic cells of a semiconductor device according to some embodiments of the present inventive concepts.

FIG. 4 illustrates a plan view showing a semiconductor device according to some embodiments of the present inventive concepts.

FIGS. 5A, 5B, 5C, and 5D illustrate cross-sectional views respectively taken along lines A-A′, B-B′, C-C′, and D-D′ of FIG. 4.

FIG. 6A illustrates an enlarged view showing an embodiment of section M depicted in FIG. 5B.

FIG. 6B illustrates a plan view taken along line L-L′ of FIG. 5B.

FIG. 6C illustrates a plan view taken along line N-N′ of FIG. 5B.

FIGS. 7A to 12C illustrate cross-sectional views showing a method of fabricating a semiconductor device according to some embodiments of the present inventive concepts.

FIGS. 13, 14, and 15 illustrate enlarged views of section M depicted in FIG. 10B, showing a method of forming a second source/drain pattern according to some embodiments of the present inventive concepts.

FIG. 16 illustrates an enlarged view showing an example of section M depicted in FIG. 5B.

### DETAILED DESCRIPTION OF EMBODIMENTS

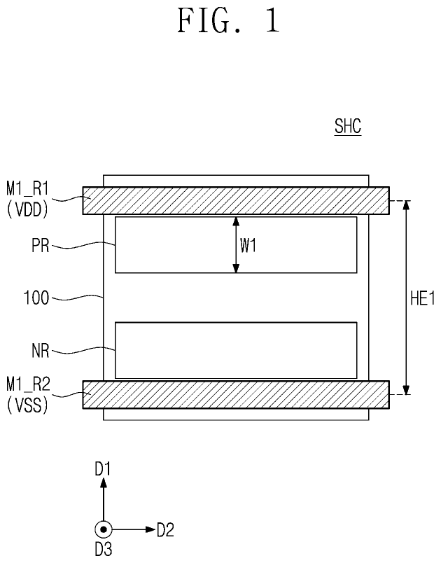

FIGS. 1, 2, and 3 illustrate conceptual views showing logic cells of a semiconductor device according to some embodiments of the present inventive concepts.

Referring to FIG. 1, a single height cell SHC may be provided. For example, a first power line M1_R1 and a second power line M1_R2 may be provided on a substrate 100. The first power line M1_R1 may be a path for providing a drain voltage VDD, for example, a power voltage. The second power line M1_R2 may be a path for providing a source voltage VSS, for example, a ground voltage.

The single height cell SHC may be defined between the first power line M1_R1 and the second power line M1_R2. The single height cell SHC may include one PMOSFET region PR and one NMOSFET region NR. For example, the single height cell SHC may have a complementary metal oxide semiconductor (CMOS) structure provided between the first power line M1_R1 and the second power line M1_R2.

Each of the PMOSFET and NMOSFET regions PR and NR may have a first width W1 in a first direction D1. A first height HE1 may be defined as a length in the first direction D1 of the single height cell SHC. The first height HE may be substantially the same as a distance (e.g., pitch) between the first power line M1_R1 and the second power line M1_R2.

The single height cell SHC may constitute one logic cell. In this description, the logic cell may mean a logic device, such as AND, OR, XOR, XNOR, and inverter, that performs a specific function. For example, the logic cell may include transistors for constituting a logic device, and may also include wiring lines that connect the transistors to each other.

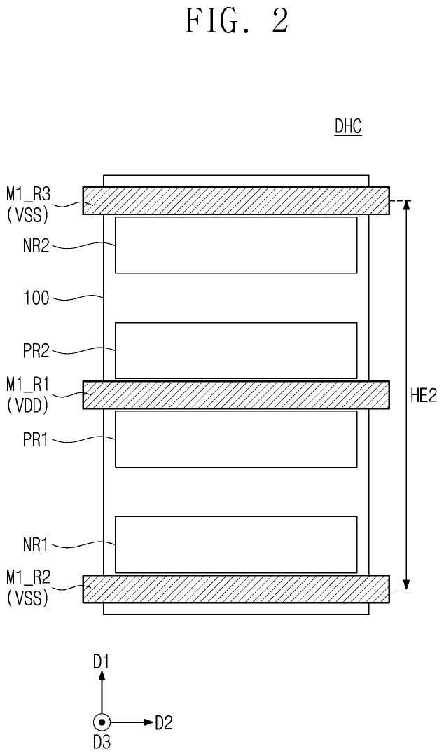

Referring to FIG. 2, a double height cell DHC may be provided. For example, a substrate 100 may be provided thereon with a first power line M1_R1, a second power line M1_R2, and a third power line M1_R3. The first power line M1_R1 may be disposed between the second power line M1_R2 and the third power line M1_R3. The third power line M1_R3 may be a path for providing a source voltage VSS.

The double height cell DHC may be defined between the second power line M1_R2 and the third power line M1_R3. The double height cell DHC may include a first PMOSFET region PR1, a second PMOSFET region PR2, a first NMOSFET region NR1, and a second NMOSFET region NR2.

The first NMOSFET region NR1 may be adjacent to the second power line M1_R2. The second NMOSFET region NR2 may be adjacent to the third power line M1_R3. The first and second PMOSFET regions PR1 and PR2 may be adjacent to the first power line M1_R1. When viewed in plan, the first power line M1_R1 may be disposed between the first and second PMOSFET regions PR1 and PR2.

As used herein, the term “about” may reflect amounts, sizes, orientations, or layouts that vary only in a small relative manner, and/or in a way that does not significantly alter the operation, functionality, or structure of certain elements.

A second height HE2 may be defined to indicate a length in the first direction D1 of the double height cell DHC. The second height HE2 may be about twice the first height HE1 of FIG. 1. The first and second PMOSFET regions PR1 and PR2 of the double height cell DHC may collectively operate as a single PMOSFET region.

Therefore, the double height cell DHC may have a PMOS transistor whose channel size is greater than that of a PMOS transistor included in the single height cell SHC discussed above in FIG. 1. For example, the channel size of the PMOS transistor included in the double height cell DHC may be about twice that of the PMOS transistor included in the single height cell SHC. The double height cell DHC may operate at a higher speed than that of the single height cell SHC. In the present inventive concepts, the double height cell DHC shown in FIG. 2 may be defined as a multi-height cell. Although not shown, the multi-height cell may include a triple height cell whose cell height is about three times that of the single height cell SHC.

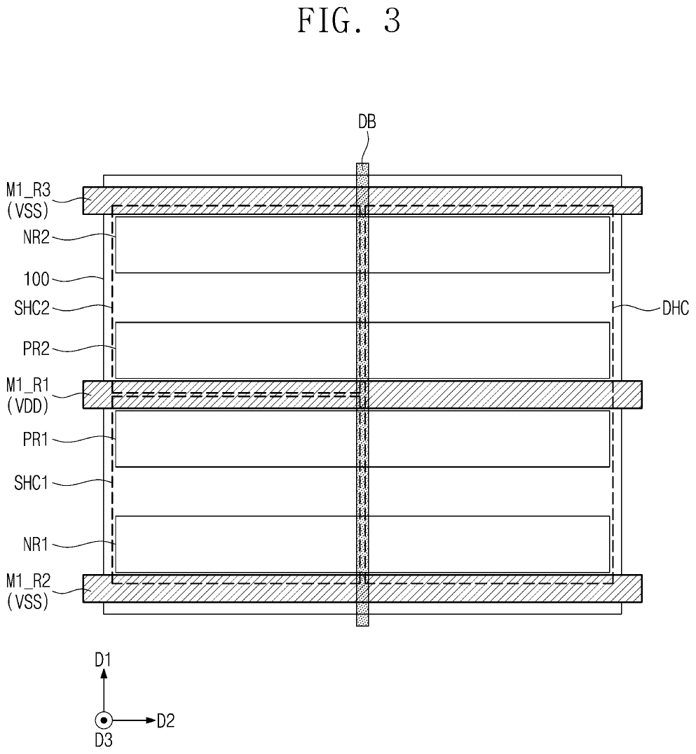

Referring to FIG. 3, a substrate 100 may be provided thereon with a first single height cell SHC1, a second single height cell SHC2, and a double height cell DHC that are two-dimensionally disposed. For example, each of the first single height cell SHC1, the second single height cell SHC2, and the double height cell DHC may be separated from each other in the first direction D1 and/or in the second direction D2 as shown, e.g., in FIG. 3. The first single height cell SHC1 may be disposed between a first power line M1_R1 and a second power line M1_R2. The second single height cell SHC2 may be disposed between the first power line M1_R1 and a third power line M1_R3. The second single height cell SHC2 may be adjacent in the first direction D1 to the first single height cell SHC1.

The double height cell DHC may be disposed between the second power line M1_R2 and the third power line M1_R3. The double height cell DHC may be adjacent in a second direction D2 to the first and second single height cells SHC1 and SHC2.

A separation structure DB may be provided between the first single height cell SHC1 and the double height cell DHC and between the second single height cell SHC2 and the double height cell DHC. The separation structure DB may electrically separate an active region of the double height cell DHC from an active region of each of the first and second single height cells SHC1 and SHC2.

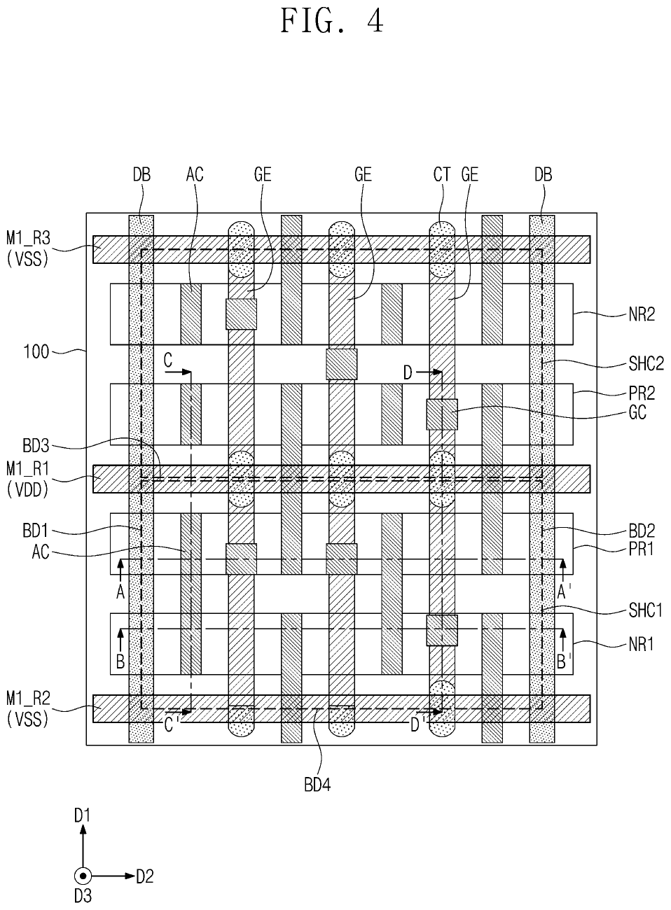

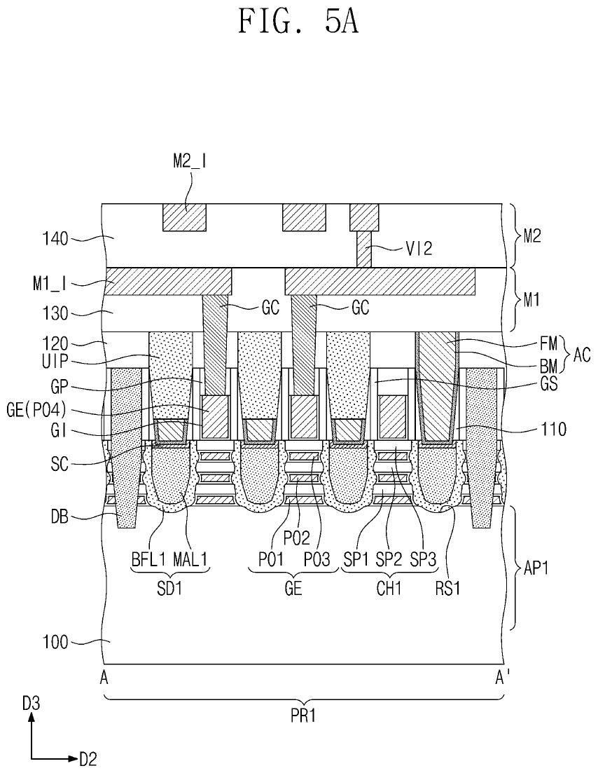

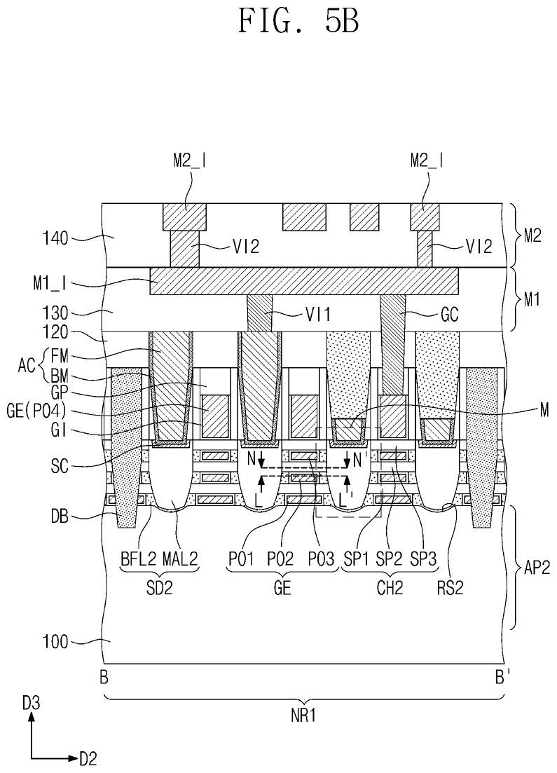

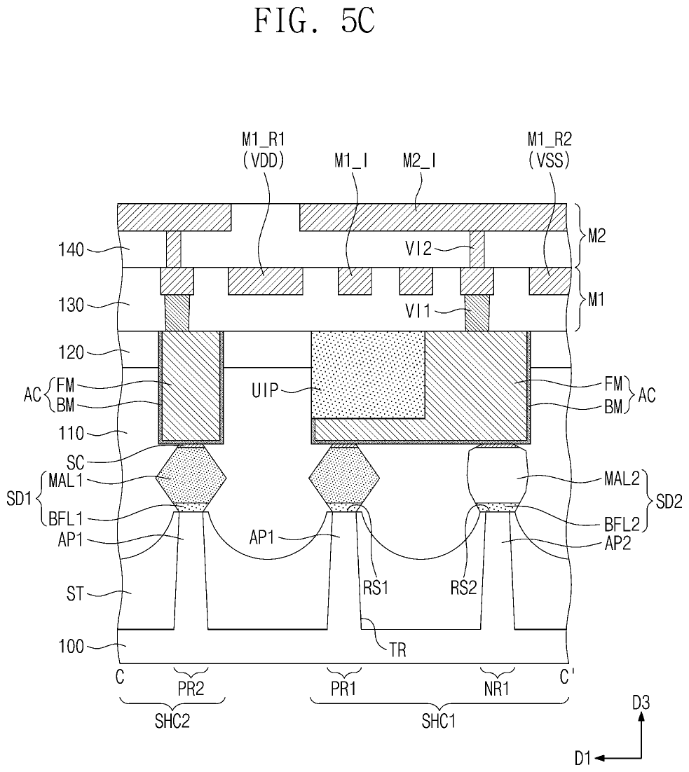

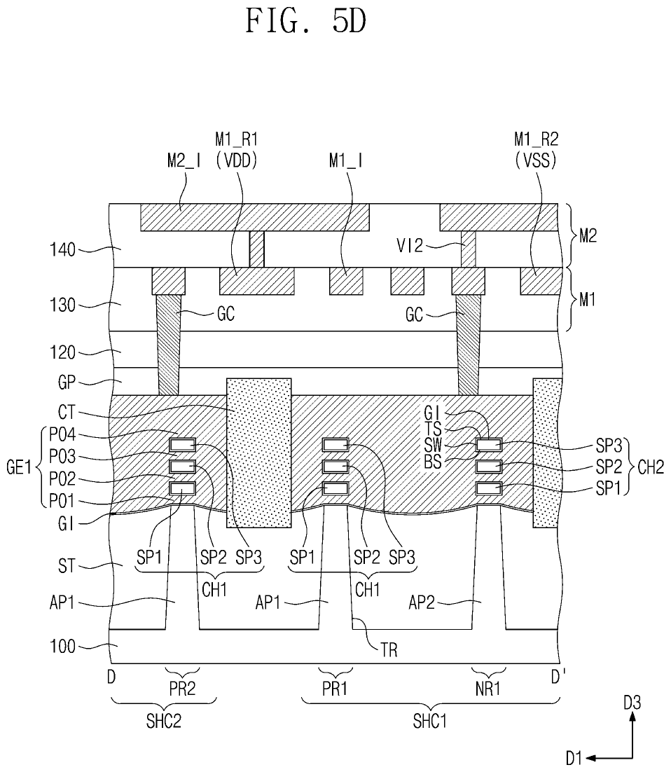

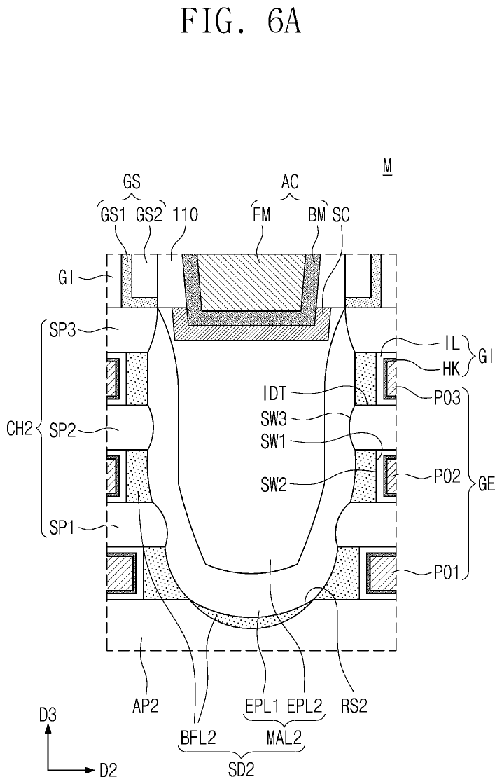

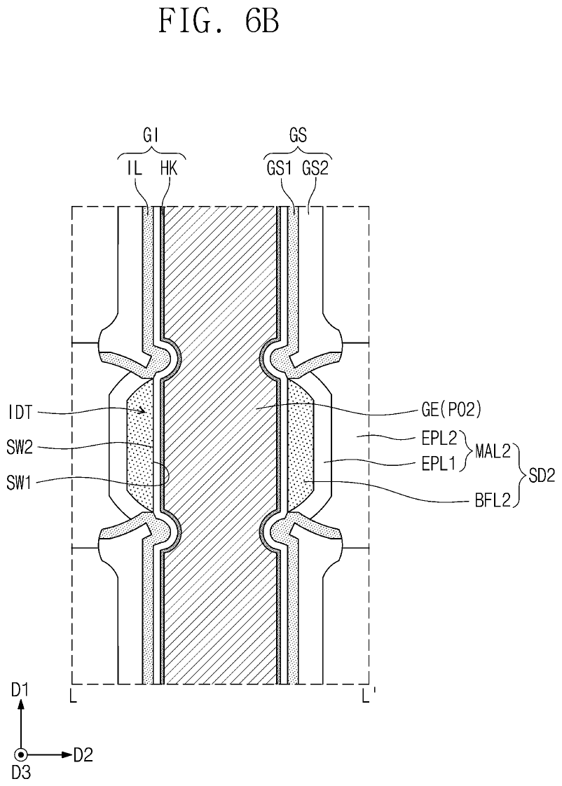

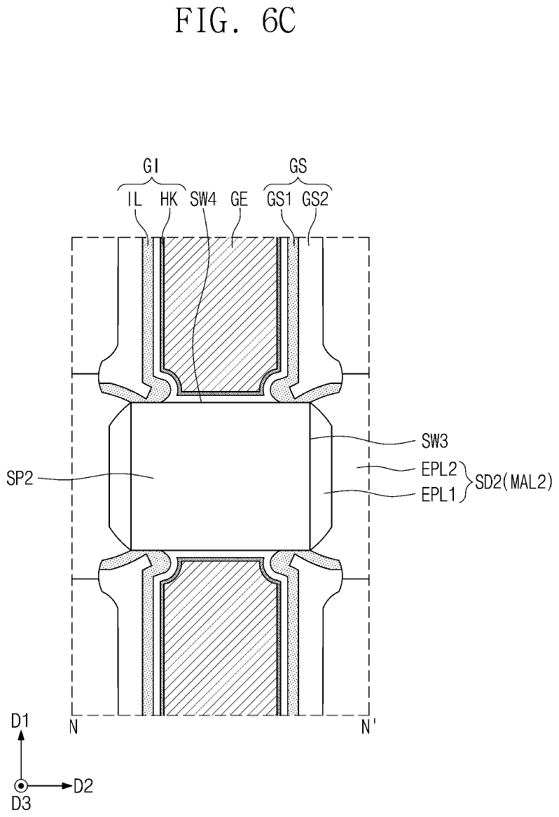

FIG. 4 illustrates a plan view showing a semiconductor device according to some embodiments of the present inventive concepts. FIGS. 5A, 5B, 5C, and 5D illustrate cross-sectional views respectively taken along lines A-A′, B-B′, C-C′, and D-D′ of FIG. 4. FIG. 6A illustrates an enlarged view showing an embodiment of section M depicted in FIG. 5B.

Referring to FIGS. 4 and 5A to 5D, first and second single height cells SHC1 and SHC2 may be provided on a substrate 100. Each of the first and second single height cells SHC1 and SHC2 may include logic transistors included in a logic circuit. The substrate 100 may be a compound semiconductor substrate or a semiconductor substrate that is formed of or includes silicon, germanium, or silicon-germanium. For example, the substrate 100 may be a silicon substrate.

An item, layer, or portion of an item or layer described as “extending” in a particular direction has a length in the particular direction and a width perpendicular to that direction, where the length is greater than the width.

The substrate 100 may have a first PMOSFET region PR1, a second PMOSFET region PR2, a first NMOSFET region NR1, and a second NMOSFET region NR2. Each of the first PMOSFET region PR1, the second PMOSFET region PR2, the first NMOSFET region NR1, and the second NMOSFET region NR2 may extend in a second direction D2. The first single height cell SHC1 may include the first NMOSFET region NR1 and the first PMOSFET region PR1, and the second single height cell SHC2 may include the second PMOSFET region PR2 and the second NMOSFET region NR2.

A first active pattern AP1 and a second active pattern AP2 may be defined by a trench TR formed on an upper portion of the substrate 100 (see, e.g., FIGS. 5C and 5D). The first active pattern AP1 may be provided on each of the first and second PMOSFET regions PR1 and PR2. The second active pattern AP2 may be provided on each of the first and second NMOSFET regions NR1 and NR2. The first and second active patterns AP1 and AP2 may extend in the second direction D2. The first and second active patterns AP1 and AP2 may be vertically protruding portions of the substrate 100.

The trench TR may be filled with a device isolation layer ST. The device isolation layer ST may be formed of or include a silicon oxide layer. The device isolation layer ST may not cover any of first and second channel patterns CH1 and CH2 which will be discussed below.

A first channel pattern CH1 may be provided on the first active pattern AP1. A second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3 that are sequentially stacked. The first, second, and third semiconductor patterns SP1, SP2, and SP3 may be spaced apart from each other in a vertical direction (or a third direction D3).

Each of the first, second, and third semiconductor patterns SP1, SP2, and SP3 may be formed of or include silicon (Si), germanium (Ge), or silicon-germanium (SiGe). For example, each of the first, second, and third semiconductor patterns SP1, SP2, and SP3 may include crystalline silicon. The first, second, and third semiconductor patterns SP1, SP2, and SP3 may be stacked nano-sheets.

According to an embodiment of the present inventive concepts, each of the first and second channel patterns CH1 and CH2 may include three nano-sheets. The present inventive concepts, however, are not limited thereto, and each of the first and second channel patterns CH1 and CH2 may independently include two or more nano-sheets.

The first, second, and third semiconductor patterns SP1, SP2, and SP3 may have different lengths in the second direction D2. In an embodiment, the second semiconductor pattern SP2 may have a length greater than that of the third semiconductor pattern SP3. The first semiconductor pattern SP1 may have a length greater than that of the second semiconductor pattern SP2. For example, the first semiconductor pattern SP1 of the first, second, and third semiconductor patterns SP1, SP2, and SP3 may be the longest. The third semiconductor pattern SP3 of the first, second, and third semiconductor patterns SP1, SP2, and SP3 may be the shortest.

A plurality of first source/drain patterns SD1 may be provided on the first active pattern AP1. A plurality of first recesses RS1 may be formed on an upper portion of the first active pattern AP1. The first source/drain patterns SD1 may be correspondingly provided in the first recesses RS1. The first source/drain patterns SD1 may be impurity regions having a first conductivity type (e.g., p-type). The first channel pattern CH1 may be interposed between a pair of first source/drain patterns SD1. For example, the pair of first source/drain patterns SD1 may be connected through the stacked first, second, and third semiconductor patterns SP1, SP2, and SP3.

A plurality of second source/drain patterns SD2 may be provided on the second active pattern AP2. A plurality of second recesses RS2 may be formed on an upper portion of the second active pattern AP2. The second source/drain patterns SD2 may be correspondingly provided in the second recesses RS2. The second source/drain patterns SD2 may be impurity regions having a second conductivity type (e.g., n-type). The second channel pattern CH2 may be interposed between a pair of second source/drain patterns SD2. For example, the pair of second source/drain patterns SD2 may be connected through the stacked first, second, and third semiconductor patterns SP1, SP2, and SP3.

The first and second source/drain patterns SD1 and SD2 may be epitaxial patterns formed by a selective epitaxial growth (SEG) process. In an embodiment, each of the first and second source/drain patterns SD1 and SD2 may have a top surface at a level substantially the same as that of a top surface of the third semiconductor pattern SP3 (e.g., the topmost semiconductor pattern). In another embodiment, at least one of the first and second source/drain patterns SD1 and SD2 may have a top surface higher than that of the third semiconductor pattern SP3.

The first source/drain patterns SD1 may be formed of or include a semiconductor element (e.g., SiGe) whose lattice constant is greater than that of a semiconductor element of the substrate 100. Therefore, a pair of first source/drain patterns SD1 may provide the first channel pattern CH1 with compressive stress. The second source/drain patterns SD2 may be formed of or include the same semiconductor element (e.g., Si) as that of the substrate 100.

Referring back to FIG. 5A, the first source/drain pattern SD1 may include a first buffer layer BFL1 and a first main layer MAL1 on the first buffer layer BFL1. The first buffer layer BFL1 may cover an inner sidewall of the first recess RS1. In an embodiment, the first buffer layer BFL1 may have a thickness that decreases in a direction from lower to upper portions thereof. For example, a thickness in the third direction D3 of the first buffer layer BFL1 on a bottom of the first recess RS1 may be greater than a thickness in the second direction D2 of the first buffer layer BFL1 on an upper portion of the first recess RS1. The first buffer layer BFL1 may have a U shape along a profile of the first recess RS1.

In an embodiment of the present inventive concepts, the first buffer layer BFL1 may have an uneven embossing shape at a sidewall thereof. For example, the sidewall of the first buffer layer BFL1 may have a wavy profile. The sidewall of the first buffer layer BFL1 may protrude toward first, second, and third inner electrodes PO1, PO2, and PO3 of a gate electrode GE which will be discussed. For example, the thickness of the first buffer layer BFL1 may be larger at vertical levels that coincide with the vertical levels of the first, second, and third semiconductor patterns SP1, SP2, and SP3, and may be smaller at vertical levels that coincide with the vertical levels of the first, second, and third inner electrodes PO1, PO2, and PO3.

The first buffer layer BFL1 may occupy a portion of the first recess RS1, and the first main layer MAL1 may fill most of the remaining unoccupied portion of the first recess RS1. The first main layer MAL1 may have a volume greater than that of the first buffer layer BFL1. For example, a ratio of volume of the first main layer MAL1 to entire volume of the first source/drain pattern SD1 may be greater than a ratio of volume of the first buffer layer BFL1 to entire volume of the first source/drain pattern SD1.

The first buffer layer BFL and the first main layer MAL1 may be formed of or include silicon-germanium (SiGe). For example, the first buffer layer BFL1 may contain germanium whose concentration is relatively low. In another embodiment of the present inventive concepts, the first buffer layer BFL1 may not include germanium (Ge), but include only silicon (Si). The germanium concentration of the first buffer layer BFL1 may range from about 0 at % to about 10 at %. For example, the germanium concentration of the first buffer layer BFL1 may range from about 2 at % to about 8 at %.

The first main layer MAL1 may contain germanium (Ge) whose concentration is relatively high. For example, the germanium concentration of the first main layer MAL1 may range from about 30 at % to about 70 at %. The germanium concentration of the first main layer MAL1 may increase in the third direction D3. For example, the first main layer MAL1 adjacent to the first buffer layer BFL1 may have a germanium concentration of about 40 at %, and an upper portion of the first main layer MAL1 may have a germanium concentration of about 60 at %.

Each of the first buffer layer BFL1 and the first main layer MAL1 may include impurities (e.g., at least one selected from boron, gallium, and indium) that cause the first source/drain pattern SD1 to have a p-type conductivity. Each of the first buffer layer BFL1 and the first main layer MAL1 may have an impurity concentration of about 1E18 atoms/cm³ to about 5E22 atoms/cm³. The impurity concentration of the first main layer MAL1 may be greater than that of the first buffer layer BFL1.

The first buffer layer BFL1 may prevent stacking faults between the first main layer MAL1 and the substrate 100 (or the first active pattern AP1) and between the first main layer MAL1 and the first, second, and third semiconductor patterns SP1, SP2, and SP3. The occurrence of stacking faults may increase a channel resistance. The stacking faults may easily occur at the bottom of the first recess RS1. Accordingly, it may be preferable that the first buffer layer BFL1 adjacent to the bottom of the first recess RS1 should have a relatively large thickness to prevent the stacking faults.

The first buffer layer BFL1 may protect the first main layer MAL1 while sacrificial layers SAL are replaced with first, second, and third inner electrodes PO1, PO2, and PO3 of a gate electrode GE which will be discussed below. For example, the first buffer layer BFL1 may prevent the first main layer MAL1 from being etched with an etching material that etches sacrificial layers SAL which will be discussed below.

A detailed description of the second source/drain pattern SD2 will be discussed below with reference to FIGS. 6A, 6B, and 6C.

Referring back to FIGS. 4 and 5A to 5D, gate electrodes GE may be formed to extend in a first direction D1, while running across the first and second channel patterns CH1 and CH2. The gate electrodes GE may be arranged at a first pitch in the second direction D2. Each of the gate electrodes GE may vertically overlap the first and second channel patterns CH1 and CH2 (see, e.g., FIGS. 5A and 5B).

The gate electrode GE may include a first inner electrode PO1 interposed between the first semiconductor pattern SP1 and the active pattern AP1 or AP2, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring back to FIGS. 5A and 5B, the first, second, and third inner electrodes PO1, PO2, and PO3 of the gate electrode GE may have different widths in the second direction D2. In an embodiment, a maximum width of the second inner electrode PO2 may be greater than that of the third inner electrode PO3. A maximum width of the first inner electrode PO1 may be greater than that of the second inner electrode PO2. As shown in FIG. 5D, the first, second, and third inner electrodes PO1, PO2, and PO3 may be integrally formed and connected to each other as the gate electrode GE surrounds each of the first, second, and third semiconductor patterns SP1, SP2, and SP3 in the first direction D1.

Referring back to FIG. 5D, the gate electrode GE may be provided on a top surface TS, a bottom surface BS, and opposite sidewalls SW of each of the first, second, and third semiconductor patterns SP1, SP2, and SP3. For example, a transistor according to the present embodiment may be a three-dimensional field effect transistor (e.g., MBCFET or GAAFET) in which the gate electrode GE three-dimensionally surrounds a channel or the first and second channel patterns CH1 and CH2.

Referring back to FIGS. 4 and 5A to 5D, representatively, the first single height cell SHC1 may have a first boundary BD1 and a second boundary BD2 that are opposite to each other in the second direction D2. The first and second boundaries BD1 and BD2 may extend in the first direction D1. The first single height cell SHC1 may have a third boundary BD3 and a fourth boundary BD4 that are opposite to each other in the first direction D1. The third and fourth boundaries BD3 and BD4 may extend in the second direction D2.

Gate cutting patterns CT may be disposed on a boundary in the second direction D2 of each of the first and second single height cells SHC1 and SHC2. For example, the gate cutting patterns CT may be disposed on the third and fourth boundaries BD3 and BD4 of the first single height cell SHC1. The gate cutting patterns CT may be arranged at the first pitch along the third boundary BD3. The gate cutting patterns CT may be arranged at the first pitch along the fourth boundary BD4. When viewed in plan, the gate cutting patterns CT on the third and fourth boundaries BD3 and BD4 may be disposed to correspondingly overlap the gate electrodes GE. The gate cutting patterns CT may be formed of or include a dielectric material, such as a silicon oxide layer, a silicon nitride layer, or a combination thereof.

The gate cutting pattern CT may separate the gate electrode GE on the first single height cell SHC1 from the gate electrode GE on the second single height cell SHC2. The gate cutting pattern CT may be interposed between the gate electrode GE on the first single height cell SHC1 and the gate electrode GE on the second single height cell SHC2, which gate electrodes GE are aligned with each other in the first direction D1. For example, the gate cutting patterns CT may divide the gate electrode GE, which extends in the first direction D1, into a plurality of gate electrodes GE each corresponding to a respective single height cell.

A pair of gate spacers GS may be disposed on opposite sidewalls of the outer electrode PO4 of the gate electrode GE (see, e.g., FIG. 5A). The gate spacers GS may extend in the first direction D1 along the gate electrode GE. The gate spacers GS may have top surfaces higher than that of the gate electrode GE. The top surfaces of the gate spacers GS may be coplanar with that of a first interlayer dielectric layer 110 which will be discussed below. In an embodiment, the gate spacers GS may be formed of or include at least one selected from SiCN, SiCON, and SiN. In another embodiment, the gate spacers GS may include a multiple layer formed of at least two selected from SiCN, SiCON, and SiN.

A gate capping pattern GP may be provided on the gate electrode GE. The gate capping pattern GP may extend in the first direction D1 along the gate electrode GE. The gate capping pattern GP may include a material having an etch selectivity with respect to first and second interlayer dielectric layers 110 and 120 which will be discussed below. For example, the gate capping pattern GP may be formed of or include at least one selected from SiON, SiCN, SiCON, and SiN.

A gate dielectric layer GI may be interposed between the gate electrode GE and the first channel pattern CH1 and between the gate electrode GE and the second channel pattern CH2. The gate dielectric layer GI may cover the top surface TS, the bottom surface BS, and the opposite sidewalls SW of each of the first, second, and third semiconductor patterns SP1, SP2, and SP3. The gate dielectric layer GI may cover a top surface of the device isolation layer ST that underlies the gate electrode GE.

In an embodiment of the present inventive concepts, the gate dielectric layer GI may be formed of or include one or more of a silicon oxide layer, a silicon oxynitride layer, and a high-k dielectric layer. The high-k dielectric layer may include a high-k dielectric material whose dielectric constant is greater than that of a silicon oxide layer. For example, the high-k dielectric material may include at least one selected from hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

In an embodiment of the present inventive concepts, the gate electrode GE may include a first metal pattern and a second metal pattern on the first metal pattern. The first metal pattern may be provided on the gate dielectric layer GI and may be adjacent to the first, second, and third semiconductor patterns SP1, SP2, and SP3. The first metal pattern may include a work-function metal that controls a threshold voltage of a transistor. A thickness and composition of the first metal pattern may be adjusted to achieve a desired threshold voltage of a transistor. For example, the first, second, and third inner electrodes PO1, PO2, and PO3 of the gate electrode GE may be formed of the first metal pattern or the work-function metal.

The first metal pattern may include a metal nitride layer. For example, the first metal pattern may include nitrogen (N) and at least one metal selected from titanium (Ti), tantalum (Ta), aluminum (Al), tungsten (W), and molybdenum (Mo). In addition, the first metal pattern may further include carbon (C). The first metal pattern may include a plurality of stacked work-function metal layers.

The second metal pattern may include metal whose resistance is less than that of the first metal pattern. For example, the second metal pattern may include at least one metal selected from tungsten (W), aluminum (Al), titanium (Ti), and tantalum (Ta). For example, the outer electrode PO4 of the gate electrode GE may include a first metal pattern and a second metal pattern on the first metal pattern.

A first interlayer dielectric layer 110 may be provided on the substrate 100. The first interlayer dielectric layer 110 may cover the gate spacers GS and the first and second source/drain patterns SD1 and SD2. The first interlayer dielectric layer 110 may have a top surface substantially coplanar with that of the gate capping pattern GP and that of the gate spacer GS. The first interlayer dielectric layer 110 may be provided thereon with a second interlayer dielectric layer 120 that covers the gate capping pattern GP. A third interlayer dielectric layer 130 may be provided on the second interlayer dielectric layer 120. A fourth interlayer dielectric layer 140 may be provided on the third interlayer dielectric layer 130. For example, the first to fourth interlayer dielectric layers 110 to 140 may include a silicon oxide layer.

Each of the first and second single height cells SHC1 and SHC2 may be provided on its opposite sides with a pair of separation structures DB that are opposite to each other in the second direction D2. For example, the pair of separation structures DB may be provided on the first and second boundaries BD1 and BD2 of the first single height cell SHC1. The separation structure DB may extend in the first direction D1 parallel to the gate electrodes GE. A pitch between the separation structure DB and its adjacent gate electrode GE may be the same as the first pitch.

The separation structure DB may penetrate the gate capping pattern GP and the gate electrode GE to extend into the first and second active patterns AP1 and AP2. The separation structure DB may penetrate an upper portion of each of the first and second active patterns AP1 and AP2. The separation structure DB may electrically separate an active region of each of the first and second single height cells SHC1 and SHC2 from active regions of neighboring cells.

Active contacts AC may be provided to penetrate the first and second interlayer dielectric layers 110 and 120 to come into electrical connection with the first and second source/drain patterns SD1 and SD2. An active contact AC may be provided on each of opposite sides of the gate electrode GE. When viewed in plan, the active contact AC may have a bar shape that extends in the first direction D1.

The active contact AC may be a self-aligned contact. For example, the gate capping pattern GP and the gate spacer GS may be used to form the active contact AC in a self-alignment manner. The active contact AC may cover, for example, at least a portion of a sidewall of the gate spacer GS. Although not shown, the active contact AC may cover a portion of the top surface of the gate capping pattern GP.

A metal-semiconductor compound layer SC, such as a silicide layer, may be interposed between the active contact AC and the first source/drain pattern SD1 and between the active contact AC and the second source/drain pattern SD2. The active contact AC may be electrically connected through the metal-semiconductor compound layer SC to one of the first and second source/drain patterns SD1 and SD2. For example, the metal-semiconductor compound layer SC may be formed of or include at least one selected from titanium silicide, tantalum silicide, tungsten silicide, nickel silicide, and cobalt silicide.

Referring back to FIG. 5C, at least one active contact AC on the first single height cell SHC1 may electrically connect the first source/drain pattern SD1 of the first PMOSFET region PR1 to the second source/drain pattern SD2 of the first NMOSFET region NR1. The active contact AC may extend in the first direction D1 from the second source/drain pattern SD2 of the first NMOSFET region NR1 to the first source/drain pattern SD1 of the first PMOSFET region PR1.

The active contact AC may include a barrier metal BM and a fill metal FM on the barrier metal BM. The barrier metal BM may surround a surface of the fill metal FM except a top surface of the fill metal FM. For example, the fill metal FM may be formed of or include at least one selected from molybdenum, tungsten, ruthenium, cobalt, and vanadium. In an embodiment of the present inventive concepts, the fill metal FM may include molybdenum. The barrier metal BM may include a metal nitride layer. The metal nitride layer may be formed of or include at least one selected from a titanium nitride (TiN) layer, a tantalum nitride (TaN) layer, a tungsten nitride (WN) layer, a nickel nitride (NiN) layer, a cobalt nitride (CON) layer, and a platinum nitride (PtN) layer.

Gate contacts GC may be provided to penetrate the third interlayer dielectric layer 130, the second interlayer dielectric layer 120, and the gate capping pattern GP to come into electrical connection with the gate electrodes GE. When viewed in plan, two gate contacts GC on the first single height cell SHC1 may be disposed to overlap the first PMOSFET region PR1. For example, two gate contacts GC on the first single height cell SHC1 may be provided on the first active pattern AP1 (see FIG. 5A). When viewed in plan, one gate contact GC on the first single height cell SHC1 may be disposed to overlap the first NMOSFET region NR1. For example, one gate contact GC on the first single height cell SHC1 may be provided on the second active pattern AP2 (see FIG. 5B).

The gate contact GC may be freely located with no limitation of position on the gate electrode GE. For example, the gate contacts GC on the second single height cell SHC2 may be correspondingly disposed on the second PMOSFET region PR2, the second NMOSFET region NR2, and the device isolation layer ST that fills the trench TR (see FIG. 4).

In an embodiment of the present inventive concepts, referring to FIGS. 5A and 5B, an upper dielectric pattern UIP may fill an upper portion of each of the active contacts AC, which upper portion is adjacent to the gate contact GC. The upper dielectric pattern UIP may have a bottom surface lower than that of the gate contact GC. For example, the upper dielectric pattern UIP may cause the active contact AC adjacent to the gate contact GC to have a top surface lower than the bottom surface of the gate contact GC. Therefore, it may be possible to prevent a short-circuit resulting from contact between the gate contact GC and its adjacent active contact AC.

A first via VI1 may be provided on the active contact AC (see, e.g., FIG. 5B). The first via VI1 may have a top surface located at the same level as that of a top surface of the gate contact GC (see FIG. 5B). In an embodiment of the present inventive concepts, the first via VI1 and the gate contact GC may be formed at the same time. The first via VI1 and the gate contact GC may include the same material. The first via VI1 and the gate contact GC may be formed of or include at least one selected from molybdenum, tungsten, ruthenium, cobalt, and vanadium.

A first metal layer M1 may be provided in the third interlayer dielectric layer 130. For example, the first metal layer M1 may include a first power line M1_R1, a second power line M1_R2, a third power line M1_R3, and first wiring lines M1_I. The lines M1_R1, M1_R2, M1_R3, and M1_I of the first metal layer M1 may extend parallel to each other in the second direction D2.

For example, the first and second power lines M1_R1 and M1_R2 may be correspondingly provided on the third and fourth boundaries BD3 and BD4 of the first single height cell SHC1. The first power line M1_R1 may extend in the second direction D2 along the third boundary BD3. The second power line M1_R2 may extend in the second direction D2 along the fourth boundary BD4.

The first wiring lines M1_I of the first metal layer M1 may be arranged at a second pitch along the first direction D1. In an embodiment, the second pitch may be less than the first pitch. Each of the first wiring lines M1_I may have a line-width less than that of each of the first, second, and third power lines M1_R1, M1_R2, and M1_R3.

The first via VI1 may electrically connect the active contact AC to a certain line of the first metal layer M1. The gate electrode GE may be electrically connected through the gate contact GC to one of the lines M1_R1, M1_R2, M1_R3, and M1_I of the first metal layer M1.

A certain line and its underlying first via VI1 of the first metal layer M1 may be formed by individual processes. For example, the certain line and its underlying first via VI1 of the first metal layer M1 may each be formed by a single damascene process. A sub-20 nm process may be employed to fabricate a semiconductor device according to the present embodiment.

A second metal layer M2 may be provided in the fourth interlayer dielectric layer 140. The second metal layer M2 may include a plurality of second wiring lines M2_I. The second wiring lines M2_I of the second metal layer M2 may each have a linear or bar shape that extends in the first direction D1. For example, the second wiring lines M2_I may extend parallel to each other in the first direction D1.

The second metal layer M2 may further include second vias VI2 that are correspondingly provided below the second wiring lines M2_I. A certain line of the first metal layer M1 may be electrically connected through the second via VI2 to a corresponding line of the second metal layer M2. For example, a certain line and its underlying second via VI2 of the second metal layer M2 may be simultaneously formed in a dual damascene process.

The first and second metal layers M1 and M2 may have their lines that are formed of or include the same or different conductive materials. For example, the first and second metal layers M1 and M2 may have their lines including at least one metal selected from copper, ruthenium, aluminum, tungsten, molybdenum, and cobalt. Although not shown, other metal layers (e.g., M3, M4, M5, etc.) may be additionally stacked on the fourth interlayer dielectric layer 140. Each of the stacked metal layers may include wiring lines for routing between cells.

The second source/drain pattern SD2 will be discussed in detail below with reference to FIG. 6A. The second source/drain pattern SD2 may include a second buffer layer BFL2 and a second main layer MAL2 on the second buffer layer BFL2. The second buffer layer BFL2 may cover an inner sidewall of the second recess RS2.

It will be understood that when an element is referred to as “contacting” or “in contact with” another element (or using any form of the word “contact”), there are no intervening elements present at the point of contact.

In an embodiment of the present inventive concepts, the second main layer MAL2 may include a first epitaxial layer EPL1 and a second epitaxial layer EPL2. The first epitaxial layer EPL1 may be in contact with the first, second, and third semiconductor patterns SP1, SP2, and SP3.

The first epitaxial layer EPL1 may partially fill the second recess RS2. The first epitaxial layer EPL1 may have a U shape. The second epitaxial layer EPL2 may be provided on the first epitaxial layer EPL1 to partially or completely fill the second recess RS2.

Each of the first and second epitaxial layers EPL1 and EPL2 may be formed of or include silicon (Si). For example, a silicon concentration of each of the first and second epitaxial layers EPL1 and EPL2 may range from about 85 at % to about 100 at %. According to the present inventive concepts, the silicon concentration of the first epitaxial layer EPL1 may be greater than that of the second epitaxial layer EPL2.

The first and second epitaxial layers EPL1 and EPL2 may include impurities (e.g., at least one selected from phosphorus, arsenic, and antimony) that cause the second source/drain pattern SD2 to have an n-type conductivity. The impurities of the first epitaxial layer EPL1 may be the same as or different from those of the second epitaxial layer EPL2. For example, the first epitaxial layer EPL1 may include arsenic (As), and the second epitaxial layer EPL2 may include phosphorus (P).

The second epitaxial layer EPL2 may have an impurity concentration greater than that of the first epitaxial layer EPL1. For example, the impurity concentration of the first epitaxial layer EPL1 may range from about 0.1 at % to about 4 at %. For example, the impurity concentration of the first epitaxial layer EPL1 may range from 0.1 at % to 4 at %. The impurity concentration of the second epitaxial layer EPL2 may range from about 4 at % to about 12 at %. For example, the impurity concentration of the second epitaxial layer EPL2 may range from 4 at % to 12 at %.

An indent region IDT may be defined between the second main layer MAL2 and the inner electrode PO1, PO2, or PO3. The indent region IDT may be surrounded by the gate dielectric layer GI, the second main layer MAL2, and the semiconductor patterns SP1, SP2, and SP3. For example, the indent region IDT may be defined in a vertical cross section of the semiconductor device (see, e.g., FIG. 5B) by a sidewall of the second main layer MAL2, a sidewall of the inner electrode PO1, PO2, and PO3, an upper surface of one of the semiconductor patterns SP1, SP2, and SP3, and a lower surface of another one of the semiconductor patterns SP1, SP2, and SP3.

The second buffer layer BFL2 may be provided in the indent region IDT. One sidewall of the second buffer layer BFL2 in the indent region IDT may be in contact with the first epitaxial layer EPL1. Another sidewall of the second buffer layer BFL2 in the indent region IDT may be in contact with the gate dielectric layer GI.

In an embodiment of the present inventive concepts, the second buffer layer BFL2 may also be interposed between the second main layer MAL2 and a bottom of the second recess RS2. The second buffer layer BFL2 may be in contact with the bottom of the second main layer MAL2.

The second buffer layer BFL2 may be formed of or include a crystalline semiconductor (e.g., monocrystalline silicon). For example, the second buffer layer BFL2 may include undoped silicon (Si), silicon-germanium (SiGe), carbon-doped silicon (Si:C), or carbon-doped silicon-germanium (SiGe:C). When the second buffer layer BFL2 includes silicon-germanium (SiGe), a germanium concentration may range from about 2 at % to about 8 at %. When the second buffer layer BFL2 includes carbon-doped silicon (Si:C), a carbon concentration may be less than 0.5 at %.

In an embodiment, the second buffer layer BFL2 may include impurities (e.g., at least one selected from phosphorus, arsenic, and antimony) that cause the second source/drain pattern SD2 to have an n-type conductivity. For example, the second buffer layer BFL2 may include arsenic (As). In another embodiment, the second buffer layer BFL2 may not include n-type impurities.

The second buffer layer BFL2 may have a first sidewall SW1 in contact with a second sidewall SW2 of the gate dielectric layer GI. Each of the first and second sidewalls SW1 and SW2 may be parallel to the third direction D3. Each of the first and second sidewalls SW1 and SW2 may be substantially flat. As the second sidewall SW2 of the gate dielectric layer GI is flat, it may be possible to prevent the occurrence of gate dielectric tail or sharp protrusion of an edge of the gate dielectric layer GI. Therefore, device electrical properties may be improved.

Each of the first, second, and third semiconductor patterns SP1, SP2, and SP3 may have a third sidewall SW3 in contact with the first epitaxial layer EPL1. The second buffer layer BFL2 in the indent region IDT may not extend to the third sidewall SW3. The third sidewall SW3 may not be flat but rather curved. In an embodiment of the present inventive concepts, the first sidewall SW1 may have a curvature less than that of the third sidewall SW3. For example, the first sidewall SW1 may have a curvature radius greater than that of the third sidewall SW3.

In some embodiments of the present inventive concepts, the second buffer layer BFL2, the first epitaxial layer EPL1, and the second epitaxial layer EPL2 may be formed by selective epitaxial growth (SEG) processes that are distinguished from each other. As the first and second epitaxial layers EPL1 and EPL2 include the same material (e.g., silicon), no interface between the first and second epitaxial layers EPL1 and EPL2 may be ascertained on an electroscopic image. However, the second buffer layer BFL2, the first epitaxial layer EPL1, and the second epitaxial layer EPL2 may be doped with different impurities to have different impurity concentrations during their selective epitaxial growth processes. The second buffer layer BFL2, the first epitaxial layer EPL1, and the second epitaxial layer EPL2 may be defined and/or distinguished from each other through a kind of impurity and a concentration profile of impurity.

In an embodiment of the present inventive concepts, the gate dielectric layer GI may include an interfacial layer IL and a high-k dielectric layer HK. The high-k dielectric layer HK may directly surround the gate electrode GE. For example, the interfacial layer IL may be formed of or include a silicon oxide layer, and the high-k dielectric layer HK may be formed of or include a high-k dielectric material. The high-k dielectric layer may HK have a higher dielectric constant than that of silicon oxide. For example, the high-k dielectric layer HK may have a dielectric constant of about 10 to about 25. In an embodiment, the interfacial layer IL between the second source/drain pattern SD2 and the inner electrode PO1, PO2, or PO3 may have a thickness greater than that of the interfacial layer IL between the semiconductor pattern SP1, SP2, or SP3 and the inner electrode PO1, PO2, or PO3.

The gate spacer GS may include a first spacer GS1 and a second spacer GS2. Each of the first and second spacers GS1 and GS2 may be formed of or include a silicon-containing dielectric material. For example, the first spacer GS1 may include silicon nitride (SiN) or carbon-containing silicon nitride (SiCN). The first spacer GS1 may have a thickness of about 1 nm to about 3 nm. The first spacer GS1 may directly cover the gate dielectric layer GI.

The second spacer GS2 may include a silicon-containing low-k dielectric material, for example, SiCON. The second spacer GS2 may be thicker than the first spacer GS1. The second spacer GS2 may have a thickness of about 5 nm to about 12 nm. The second spacer GS2 may have a dielectric constant less than that of the first spacer GS1.

As a comparative example of the present inventive concepts, the second buffer layer BFL2 may pass over the indent region IDT to extend onto the third sidewall SW3 of each of the first, second, and third semiconductor patterns SP1, SP2, and SP3. For example, the third sidewall SW3 of each of the first, second, and third semiconductor patterns SP1, SP2, and SP3 may be in contact not with the first epitaxial layer EPL1 but with the second buffer layer BFL2. According to the comparative example, the second buffer layer BFL2 may have a relatively large volume ratio in the second source/drain pattern SD2. When the second buffer layer BFL2 is present on the third sidewall SW3 of each of the first, second, and third semiconductor patterns SP1, SP2, and SP3, a source/drain junction overlap may be deficient which may cause an increase in a channel resistance. In addition, there may be a reduction in volume fraction of the second main layer MAL2 including high-concentration impurities in the second source/drain pattern SD2, and thus electrical properties of the transistor may be deteriorated.

In contrast, according to the present inventive concepts, the second buffer layer BFL2 may locally exist only in the indent region IDT, and may not reside on the third sidewall SW3 of each of the first, second, and third semiconductor patterns SP1, SP2, and SP3. A leakage current between the second main layer MAL2 and the first, second, and third inner electrodes PO1, PO2, and PO3 may be prevented by way of the second buffer layer BFL2 formed in the indent region IDT. Moreover, the second main layer MAL2 may be in contact with the first, second, and third semiconductor patterns SP1, SP2, and SP3, and therefore a channel resistance may decrease. Furthermore, there may be an increase in volume fraction of the second main layer MAL2 including high-concentration impurities in the second source/drain pattern SD2, and thus electrical properties of the transistor may be improved.

FIG. 6B illustrates a plan view taken along line L-L′ of FIG. 5B. FIG. 6B may be a plan view of a semiconductor device obtained when the semiconductor device is planarized until a level (e.g., line L-L′) of the second inner electrode PO2. Referring to FIG. 6B, the indent region IDT may be defined between the gate spacers GS that are adjacent to each other in the first direction D1. The second buffer layer BFL2 may be provided in the indent region IDT. The first epitaxial layer EPL1 and the second epitaxial layer EPL2 may be provided on the second buffer layer BFL2.

The gate dielectric layer GI may be interposed between the second buffer layer BFL2 and the second inner electrode PO2. The second buffer layer BFL2 may have a first sidewall SW1 in contact with a second sidewall SW2 of the gate dielectric layer GI. The first sidewall SW1 and the second sidewall SW2 may be flat in the first direction D1.

FIG. 6C illustrates a plan view taken along line N-N′ of FIG. 5B. FIG. 6C may be a plan view of a semiconductor device obtained when the semiconductor device is planarized until a level (e.g., line N-N′) of the second semiconductor pattern SP2. Referring to FIG. 6C, the second semiconductor pattern SP2 may be provided between the gate spacers GS that are adjacent to each other in the first direction D1.

The second semiconductor pattern SP2 may have a third sidewall SW3 in the first direction D1 and a fourth sidewall SW4 in the second direction D2. The gate dielectric layer GI and the gate electrode GE may be provided on the fourth sidewall SW4 of the second semiconductor pattern SP2.

The first epitaxial layer EPL1 and the second epitaxial layer EPL2 may be provided on the third sidewall SW3 of the second semiconductor pattern SP2. The first epitaxial layer EPL1 may be in contact with the third sidewall SW3 of the second semiconductor pattern SP2. The second buffer layer BFL2 may be omitted on the third sidewall SW3 of the second semiconductor pattern SP2.

According to an embodiment of the present inventive concepts, the first epitaxial layer EPL1 and the second epitaxial layer EPL2 may constitute the second main layer MAL2 having a high impurity concentration. As the second main layer MAL2 of the second source/drain pattern SD2 is in contact with the second semiconductor pattern SP2, the transistor may have a relatively low channel resistance.

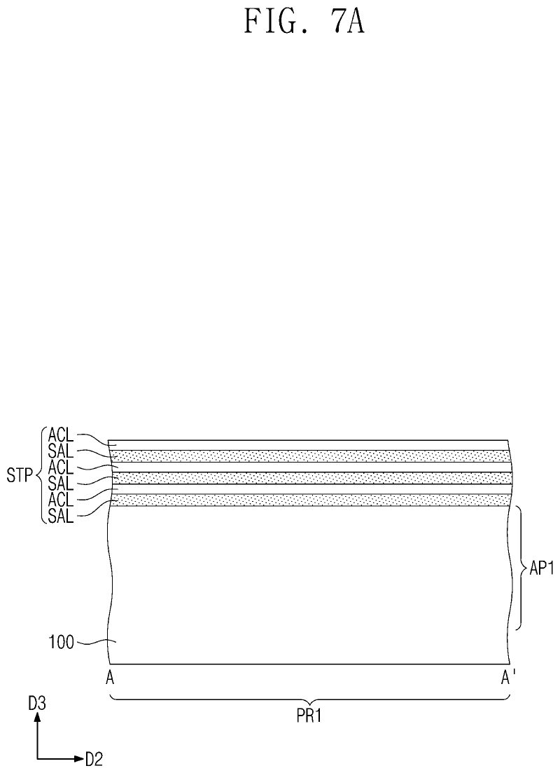

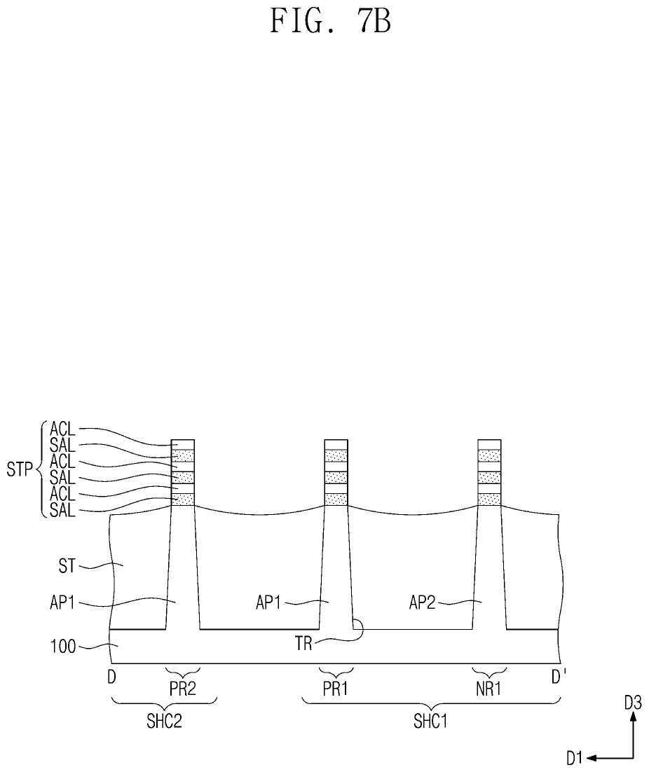

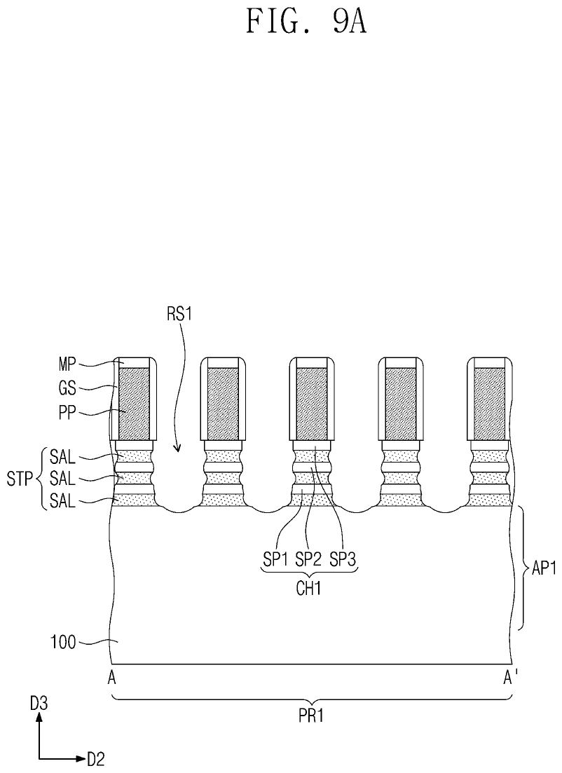

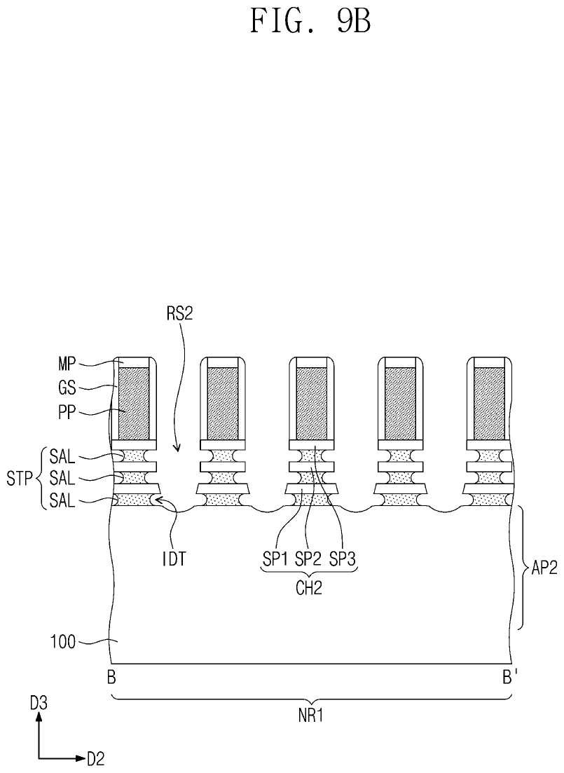

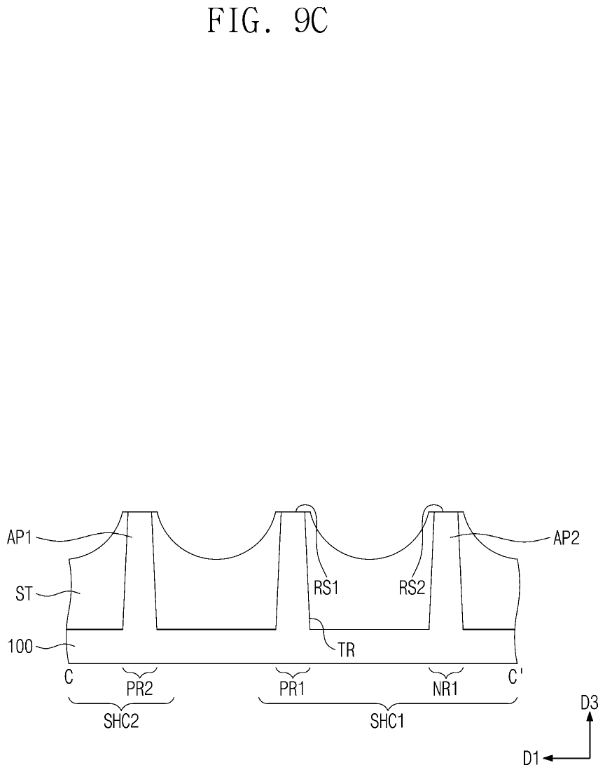

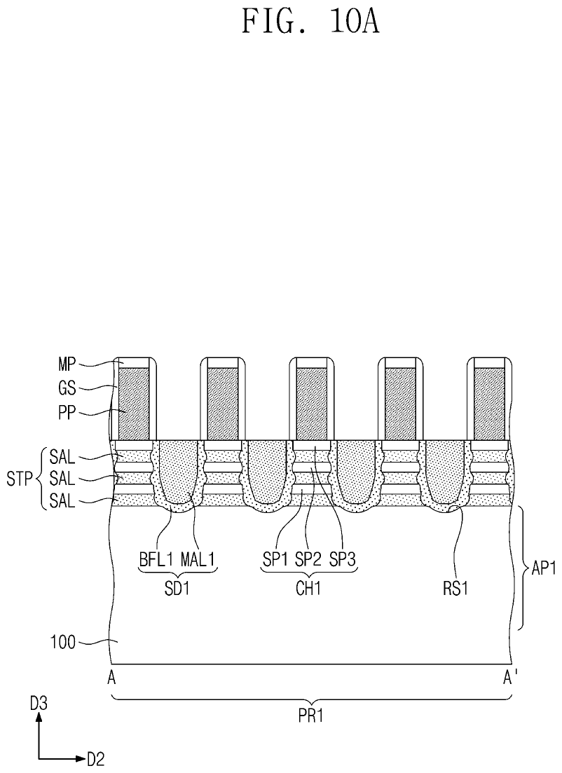

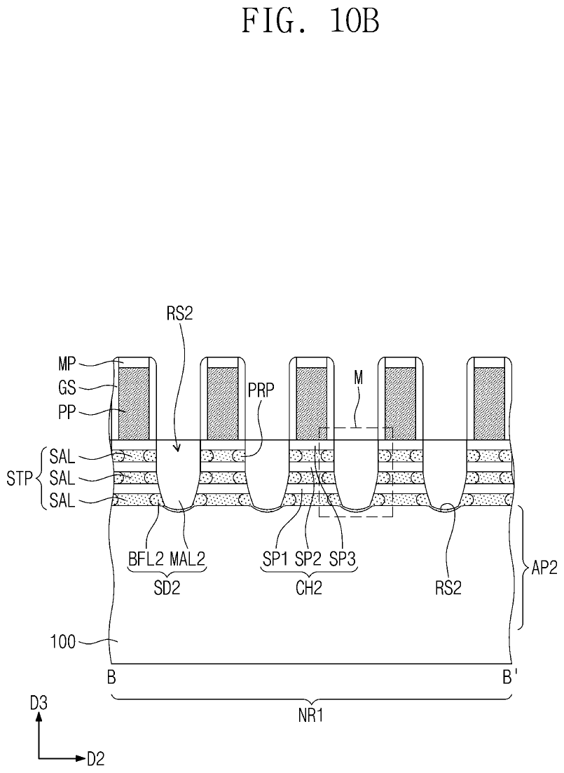

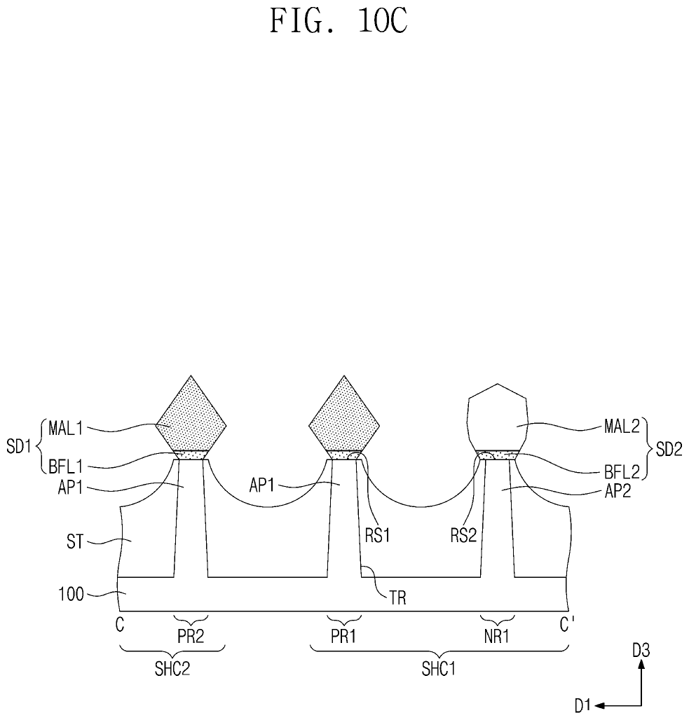

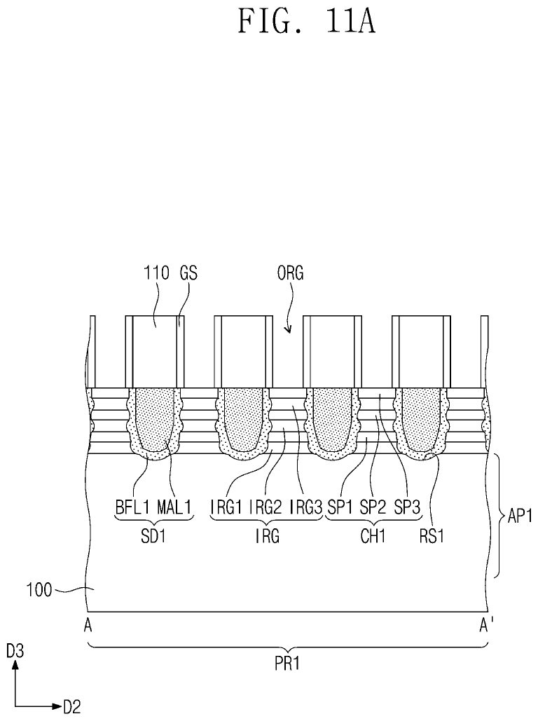

FIGS. 7A to 12C illustrate cross-sectional views showing a method of fabricating a semiconductor device according to some embodiments of the present inventive concepts. In detail, FIGS. 7A, 8A, 9A, 10A, 11A, and 12A illustrate cross-sectional views taken along line A-A′ of FIG. 4. FIGS. 9B, 10B, 11B, and 12B illustrate cross-sectional views taken along line B-B′ of FIG. 4. FIGS. 9C and 10C illustrate cross-sectional views taken along line C-C′ of FIG. 4. FIGS. 7B, 8B, 11C, and 12C illustrate cross-sectional views taken along line D-D′ of FIG. 4.

Referring to FIGS. 7A and 7B, a substrate 100 may be provided which includes first and second PMOSFET regions PR1 and PR2 and first and second NMOSFET regions NR1 and NR2. Active layers ACL and sacrificial layers SAL may be alternately formed on the substrate 100. The active layers ACL may be formed of or include one of silicon (Si), germanium (Ge), and silicon-germanium (SiGe), and the sacrificial layers SAL may be formed of or include another of silicon (Si), germanium (Ge), and silicon-germanium (SiGe).

The sacrificial layer SAL may include a material having an etch selectivity with respect to the active layer ACL. For example, the active layers ACL may include silicon (Si), and the sacrificial layers SAL may include silicon-germanium (SiGe). Each of the sacrificial layers SAL may have a germanium concentration of about 10 at % to about 30 at %.

Mask patterns may be correspondingly formed on the first and second PMOSFET regions PR1 and PR2 and the first and second NMOSFET regions NR1 and NR2 of the substrate 100. The mask pattern may have a linear or bar shape that extends in a second direction D2.

A patterning process may be performed in which the mask patterns are used as an etching mask to form a trench TR that defines a first active pattern AP1 and a second active pattern AP2. The first active pattern AP1 may be formed on each of the first and second PMOSFET regions PR1 and PR2. The second active pattern AP2 may be formed on each of the first and second NMOSFET regions NR1 and NR2.

A stack pattern STP may be formed on each of the first and second active patterns AP1 and AP2. The stack pattern STP may include the active layers ACL and the sacrificial layers SAL that are alternately stacked. During the patterning process, the stack pattern STP may be formed simultaneously with the first and second active patterns AP1 and AP2.

A device isolation layer ST may be formed to fill the trench TR. For example, a dielectric layer may be formed on a front surface of the substrate 100 to cover the stack patterns STP and the first and second active patterns AP1 and AP2. The dielectric layer may be recessed until the stack patterns STP are exposed, and thus the device isolation layer ST may be formed.

The device isolation layer ST may be formed of or include a dielectric material, such as a silicon oxide layer. The stack patterns STP may be exposed upwardly from the device isolation layer ST. For example, the stack patterns STP may vertically protrude upwards from the device isolation layer ST.

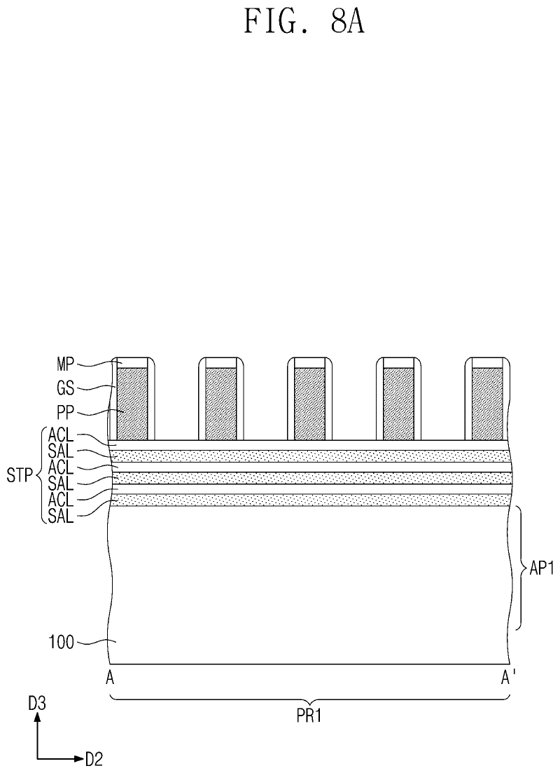

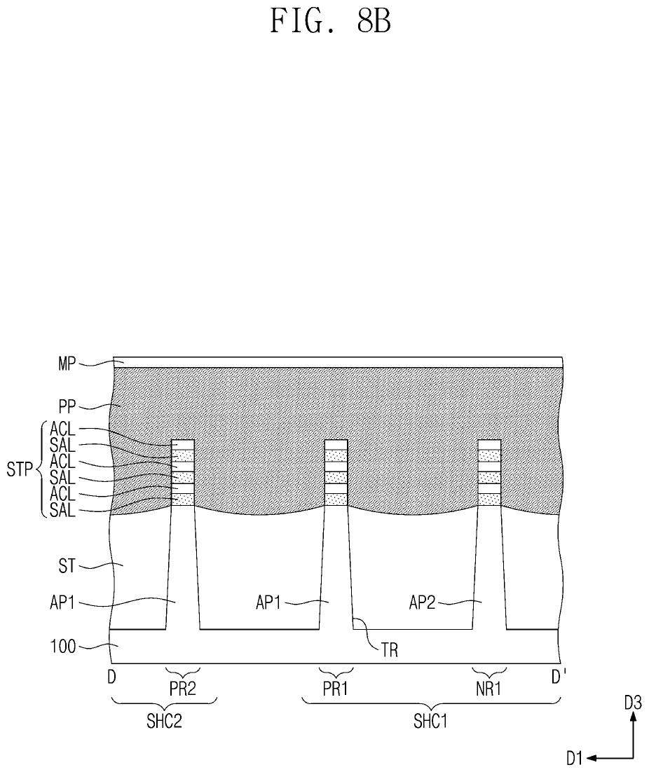

Referring to FIGS. 8A and 8B, sacrificial patterns PP running across the stack patterns STP may be formed on the substrate 100. Each of the sacrificial patterns PP may be formed to have a linear or bar shape that extends in a first direction D1. The sacrificial patterns PP may be arranged at a first pitch along the second direction D2.

For example, the formation of the sacrificial patterns PP may include forming a sacrificial layer on the front surface of the substrate 100, forming hardmask patterns MP on the sacrificial layer, and using the hardmask patterns MP as an etching mask to pattern the sacrificial layer. The sacrificial layer may be formed of or include, for example, polysilicon.

A pair of gate spacers GS may be formed on opposite sidewalls of each of the sacrificial patterns PP. The formation of the gate spacers GS may include conformally forming a gate spacer layer on the front surface of the substrate 100 and anisotropically etching the gate spacer layer. In an embodiment of the present inventive concepts, the gate spacer GS may be a multiple layer including at least two layers (e.g., GS1 and GS2 of FIG. 6A).

Referring to FIGS. 9A to 9C, first recesses RS1 may be formed in the stack pattern STP on the first active pattern AP1. Second recesses RS2 may be formed in the stack pattern STP on the second active pattern AP2. During the formation of the first and second recesses RS1 and RS2, the device isolation layer ST may further be recessed on opposite sides of each of the first and second active patterns AP1 and AP2 (see FIG. 9C).

For example, the gate spacer GS may be used as an etching mask to etch the stack pattern STP on the first active pattern AP1, thereby forming the first recesses RS1. The first recess RS1 may be formed between a pair of sacrificial patterns PP. The gate spacer GS may be used as an etching mask to etch the stack pattern STP on the second active pattern AP2, thereby forming the second recesses RS2. The second recess RS2 may be formed between a pair of sacrificial patterns PP.

In an embodiment of the present inventive concepts, the first and second recesses RS1 and RS2 may be sequentially formed in different processes. In another embodiment of the present inventive concepts, the first and second recesses RS1 and RS2 may be simultaneously formed in the same process.

The first and second recesses RS1 and RS2 may expose the sacrificial layers SAL. According to an embodiment of the present inventive concepts, a selective etching process may be performed on the exposed sacrificial layers SAL. The etching process may include a wet etching process that selectively etches only silicon-germanium. In the etching process, each of the sacrificial layers SAL may be indented to form indent regions. The indent region may allow the sacrificial layer SAL to have a concave sidewall. The indent region may cause each of the first and second recesses RS1 and RS2 to have an uneven embossing shape at a sidewall thereof. For example, the sidewalls of the first and second recesses RS1 and RS2 may have a wavy profile. For example, a center region of a sacrificial layer SAL in the vertical direction may be more recessed than top and bottom regions of the sacrificial layer, while top and bottom regions of the semiconductor patterns SP1, SP2, and SP3 defined by the recess may be more recessed than center regions thereof in the vertical direction. However, the inventive concept is not limited thereto, and some or all of the semiconductor patterns SP1, SP2, and SP3 may have a flat profile, a slanted profile, or a profile having another shape.

The active layers ACL may be formed into first, second, and third semiconductor patterns SP1, SP2, and SP3 that are sequentially stacked between neighboring first recesses RS1. The active layers ACL may be formed into first, second, and third semiconductor patterns SP1, SP2, and SP3 that are sequentially stacked between neighboring second recesses RS2. A first channel pattern CH1 may be constituted by the first, second, and third semiconductor patterns SP1, SP2, and SP3 between neighboring first recesses RS1. A second channel pattern CH2 may be constituted by the first, second, and third semiconductor patterns SP1, SP2, and SP3 between neighboring second recesses RS2.

According to an embodiment of the present inventive concepts, an additional wet etching process may further be performed on the sacrificial layers SAL exposed by the second recess RS2. Thus, an indent region IDT formed by the second recess RS2 may be formed deeper than the indent region formed by the first recess RS1 (see FIG. 9B). A length in the second direction D2 of the sacrificial layer SAL on the second active pattern AP2 may be less than a length in the second direction D2 of the sacrificial layer SAL on the first active pattern AP1.

Referring to FIGS. 10A to 10C, first source/drain patterns SD1 may be correspondingly formed in the first recesses RS1. The first source/drain pattern SD1 may include a first buffer layer BFL1 and a first main layer MAL1. Second source/drain patterns SD2 may be correspondingly formed in the second recesses RS2. The second source/drain pattern SD2 may include a second buffer layer BFL2 and a second main layer MAL2.

For example, a first selective epitaxial growth (SEG) process may be performed in which an inner wall of the first recess RS1 is used as a seed layer to form the first buffer layer BFL1. The first buffer layer BFL1 may be grown from a seed, or the first, second, and third semiconductor patterns SP1, SP2, and SP3 and the sacrificial layers SAL. For example, the first SEG process may include chemical vapor deposition (CVD) or molecular beam epitaxy (MBE).

The first buffer layer BFL1 may be formed of or include a semiconductor element (e.g., SiGe) whose lattice constant is greater than that of a semiconductor element of the substrate 100. The first buffer layer BFL1 may contain germanium whose concentration is relatively low. In another embodiment of the present inventive concepts, the first buffer layer BFL1 may not include germanium (Ge), but include only silicon (Si). The first buffer layer BFL1 may have a germanium concentration of about 0 at % to about 10 at %, for example, of about 2 at % to about 8 at %.

The first main layer MAL1 filling the first recess RS1 may be formed on the first buffer layer BFL1. A second SEG process may be performed in which an inner wall of the first buffer layer BFL1 is used as a seed layer to form the first main layer MAL1. The first main layer MAL1 may be formed of or include a semiconductor element (e.g., SiGe) whose lattice constant is greater than that of a semiconductor element of the substrate 100. The first main layer MAL1 may contain germanium (Ge) whose concentration is relatively high. For example, the germanium concentration of the first main layer MAL1 may range from about 30 at % to about 70 at %. The germanium concentration of the first main layer MAL1 may increase in a third direction D3. The first buffer layer BFL1 and the first main layer MAL1 may be implanted with impurities (e.g., boron, gallium, or indium) that cause the first source/drain pattern SD1 to have a p-type conductivity.

The second buffer layer BFL2 may be formed in the second recess RS2, and the formation of the second buffer layer BFL2 may be substantially the same as or similar to the formation of the first buffer layer BFL1 discussed above. The second main layer MAL2 may be formed on the second buffer layer MAL2. The following will describe in detail the formation of the second buffer layer BFL2 and the second main layer MAL2.

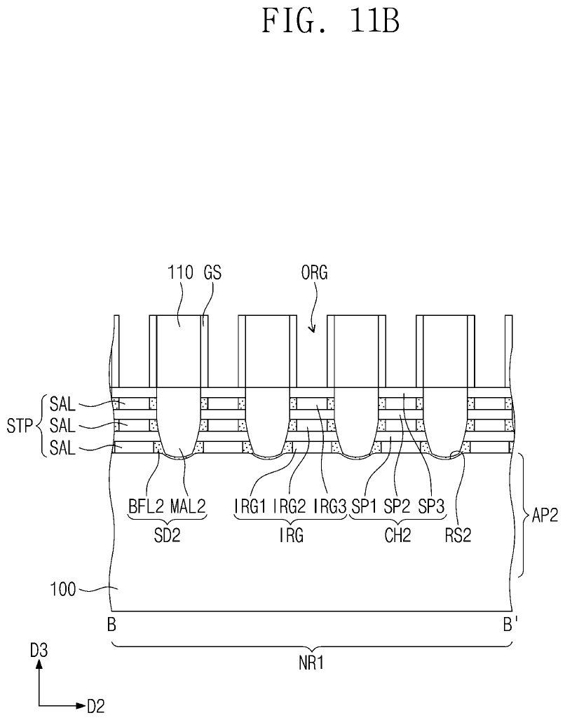

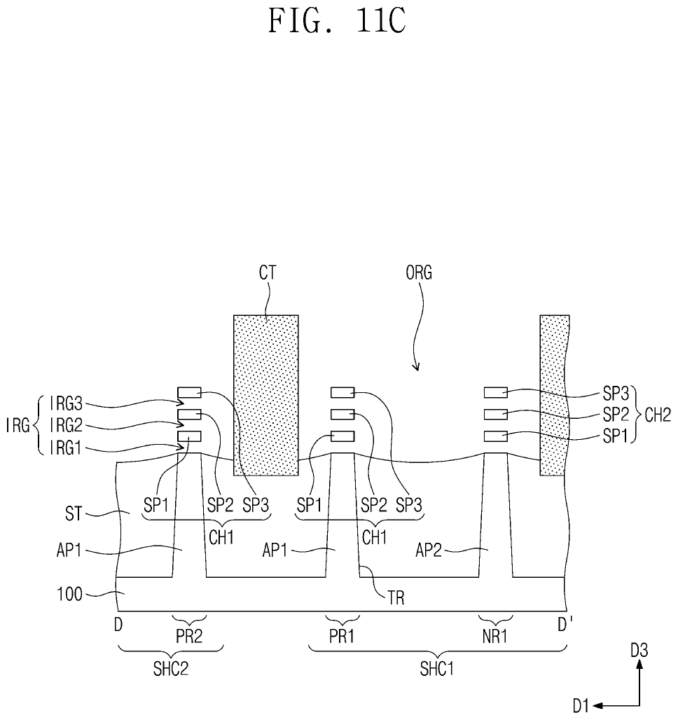

Referring to FIGS. 11A to 11C, a first interlayer dielectric layer 110 may be formed to cover the first and second source/drain patterns SD1 and SD2, the hardmask patterns MP, and the gate spacers GS. For example, the first interlayer dielectric layer 110 may include a silicon oxide layer.

The first interlayer dielectric layer 110 may be planarized until top surfaces of the sacrificial patterns PP are exposed. An etch-back or chemical mechanical polishing (CMP) process may be used to planarize the first interlayer dielectric layer 110. The hardmask patterns MP may all be removed during the planarization process. As a result, the first interlayer dielectric layer 110 may have a top surface coplanar with those of the sacrificial patterns PP and those of the gate spacers GS.

A photolithography process may be used to selectively open one region of the sacrificial pattern PP. For example, it may be possible to selectively open a region of the sacrificial pattern PP on the third and fourth boundaries BD3 and BD4 of the first single height cell SHC1. The opened portion of the sacrificial pattern PP may be selectively etched and removed. A space where the sacrificial pattern PP is removed may be filled with a dielectric material to form a gate cutting pattern CT (see FIG. 11C).

The exposed sacrificial patterns PP may be selectively removed. The removal of the sacrificial patterns PP may form an outer region ORG that exposes the first and second channel patterns CH1 and CH2 (see FIG. 11C). The removal of the sacrificial patterns PP may include performing a wet etching process using an etchant that selectively etches polysilicon.

The sacrificial layers SAL exposed through the outer region ORG may be selectively removed to form inner regions IRG (see FIG. 11C) between adjacent semiconductor patterns SP1, SP2, and SP3. For example, an etching process that selectively etches the sacrificial layers SAL may be performed such that only the sacrificial layers SAL may be removed while leaving the first, second, and third semiconductor patterns SP1, SP2, and SP3. The etching process may have a high etch rate with respect to silicon-germanium having a relatively high germanium concentration. For example, the etching process may have a high etch rate with respect to silicon-germanium whose germanium concentration is greater than about 10 at %.

During the etching process, the sacrificial layers SAL may be removed from the first and second PMOSFET regions PR1 and PR2 and from the first and second NMOSFET regions NR1 and NR2. The etching process may be a wet etching process. An etching material used for the etching process may promptly etch the sacrificial layer SAL whose germanium concentrate is relatively high. The first and second buffer layers BFL1 and BFL2 each having a relative low germanium concentration may protect the first and second source/drain patterns SD1 and SD2 during the etching process.

Referring back to FIG. 11B, on the second active pattern AP2, after the removal of the sacrificial layer SAL, an etching process may further be performed to partially remove the second buffer layer BFL2. Thus, a protrusion of the second buffer layer BFL2 may be selectively removed.

Referring back to FIG. 11C, as the sacrificial layers SAL are selectively removed, only the first, second, and third semiconductor patterns SP1, SP2, and SP3 may remain on each of the first and second active patterns AP1 and AP2. The removal of the sacrificial layers SAL may form first, second, and third inner regions IRG1, IRG3, and IRG3. For example, the first inner region IRG1 may be formed between the active pattern AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

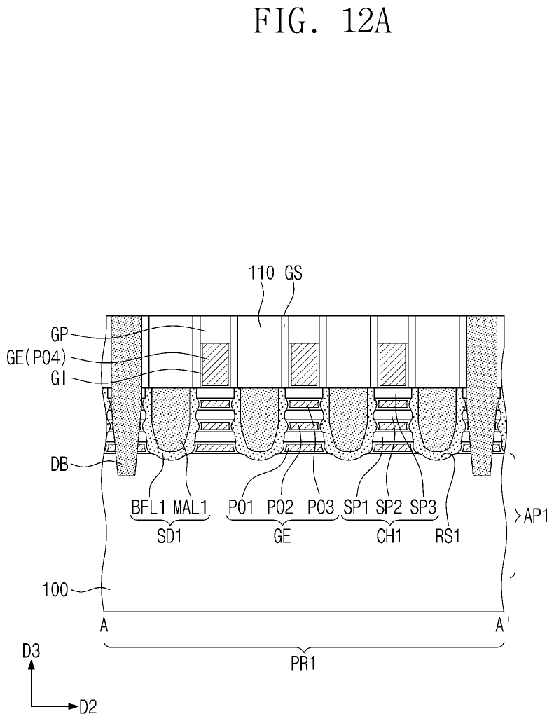

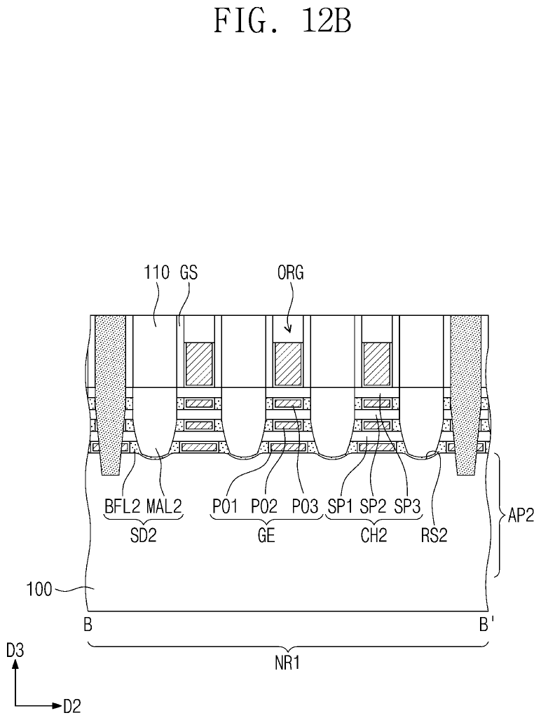

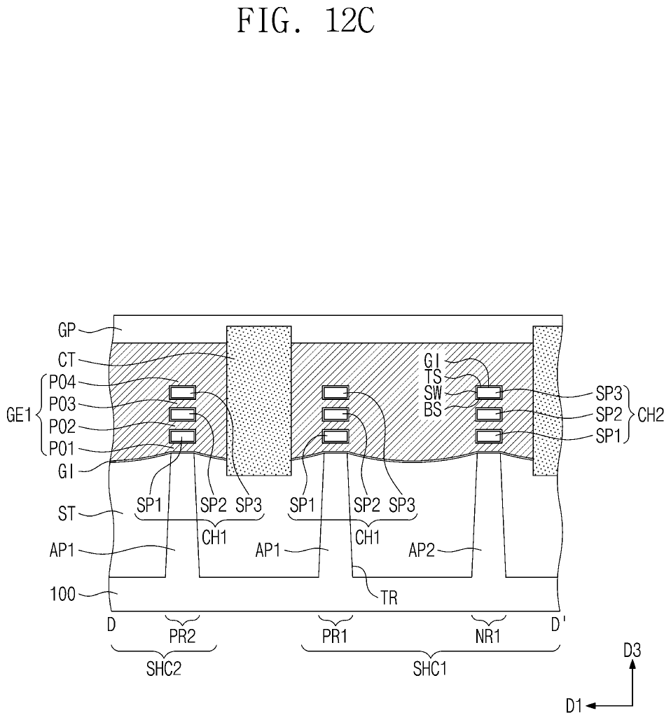

Referring to FIGS. 12A to 12C, a gate dielectric layer GI may be formed on the exposed first, second, and third semiconductor patterns SP1, SP2, and SP3. The gate dielectric layer GI may be formed to surround each of the first, second, and third semiconductor patterns SP1, SP2, and SP3. The gate dielectric layer GI may be formed in each of the first, second, and third inner regions IRG1, IRG2, and IRG3. The gate dielectric layer GI may also be formed in the outer region ORG.

A gate electrode GE may be formed on the gate dielectric layer GI. The gate electrode GE may include first, second, and third inner electrodes PO1, PO2, and PO3 that are respectively formed in the first, second, and third inner regions IRG1, IRG2, and IRG3, and may also include an outer electrode PO4 formed in the outer region ORG. The gate electrode GE may be recessed to have a reduced height. A gate capping pattern GP may be formed on the recessed gate electrode GE.

Referring back to FIGS. 5A to 5D, a second interlayer dielectric layer 120 may be formed on the first interlayer dielectric layer 110. The second interlayer dielectric layer 120 may be formed of or include a silicon oxide layer. Active contacts AC may be formed to penetrate the second and first interlayer dielectric layers 120 and 110 to come into electrical connection with the first and second source/drain patterns SD1 and SD2.

The formation of the active contact AC may include using the gate spacer GS to form a contact hole in a self-alignment manner, forming a barrier metal BM in the contact hole, and forming a fill metal FM on the barrier metal BM. The barrier metal BM may be conformally formed, and may be formed of or include a metal layer and a metal nitride layer. The fill metal FM may be formed of or include metal whose resistance is low.

A third interlayer dielectric layer 130 may be formed on the second interlayer dielectric layer 120. A gate contact GC may be formed to penetrate the third interlayer dielectric layer 130, the second interlayer dielectric layer 120, and the gate capping pattern GP to come into connection with the gate electrode GE. A first via VI1 may be formed to penetrate the third interlayer dielectric layer 130 to come into connection with the active contact AC. In an embodiment, the gate contact GC and the first via VI1 may be formed together with each other.

A first metal layer M1 may be formed in the third interlayer dielectric layer 130. For example, lines M1_R1, M1_R2, M1_R3, and M1_I may be formed in an upper portion of the third interlayer dielectric layer 130 to correspondingly come into connection with the gate contact GC and the first via VI1. A fourth interlayer dielectric layer 140 may be formed on the third interlayer dielectric layer 130. A second metal layer M2 may be formed in the fourth interlayer dielectric layer 140.

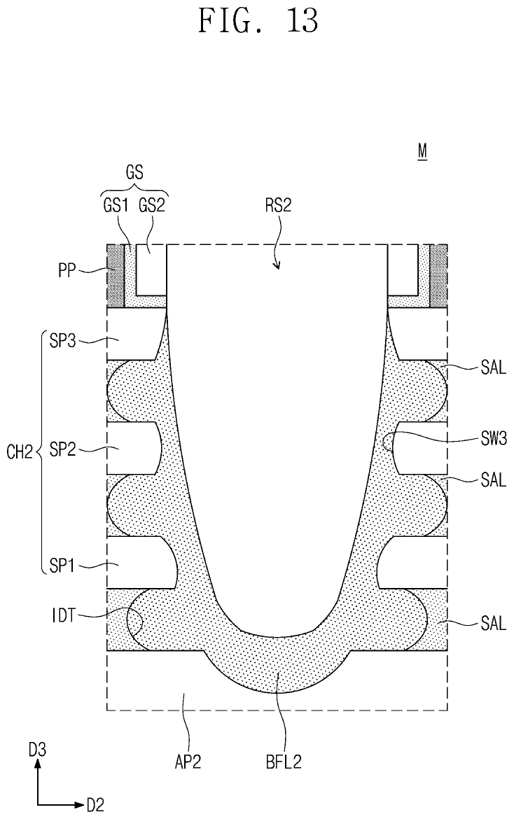

FIGS. 13, 14, and 15 illustrate enlarged views of section M depicted in FIG. 10B, showing a method of forming a second source/drain pattern according to some embodiments of the present inventive concepts.

Referring to FIG. 13, a second buffer layer BFL2 may be formed by performing a third SEG process in which an inner wall of the second recess RS2 is used as a seed layer. The second buffer layer BFL2 may be grown from a seed, or the first, second, and third semiconductor patterns SP1, SP2, and SP3 and the sacrificial layers SAL. The third SEG process may be performed such that the second buffer layer BFL2 may completely fill the indent region IDT. The third SEG process may be performed such that the second buffer layer BFL2 may partially fill the second recess RS2. The third SEG process may cause the second buffer layer BFL2 to directly cover the third sidewall SW3 of each of the first, second, and third semiconductor patterns SP1, SP2, and SP3.

The second buffer layer BFL2 may be formed of or include undoped silicon (Si), silicon-germanium (SiGe), carbon-doped silicon (Si:C), or carbon-doped silicon-germanium (SiGe:C). In an embodiment, the second buffer layer BFL2 may be doped with n-type impurities (e.g., at least one selected from phosphorus, arsenic, and antimony). In another embodiment, the second buffer layer BFL2 may not include n-type impurities. For example, the second buffer layer BFL2 may be formed of undoped silicon (Si).

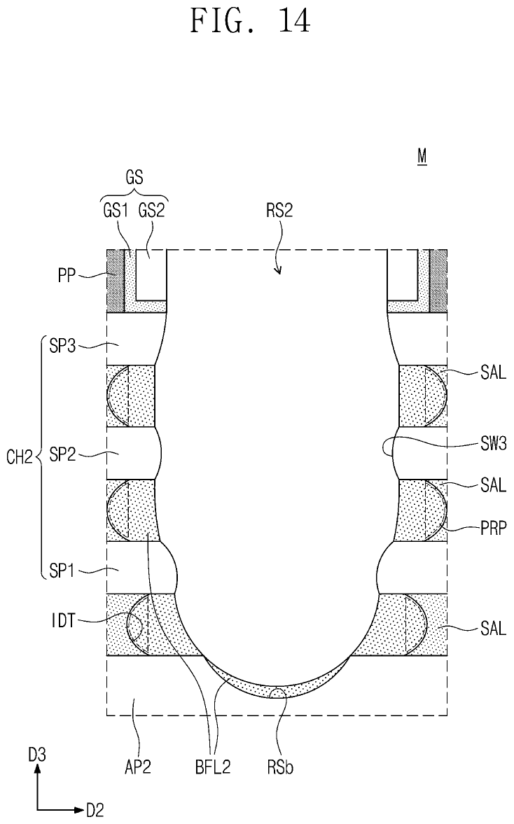

Referring to FIG. 14, an etch-back process may be performed on the second buffer layer BFL2. The etch-back process may include a selective etching process performed on the second buffer layer BFL2. The etch-back process may be executed until the third sidewall SW3 of each of the first, second, and third semiconductor patterns SP1, SP2, and SP3 are exposed. Thus, the second buffer layer BFL2 may remain only in the indent region IDT and at the bottom RSb of the second recess RS2.

The second buffer layer BFL2 in the indent region IDT may include a protrusion PRP. The protrusion PRP may convexly protrude toward the sacrificial layer SAL. The protrusion PRP may be selectively removed by an additional etching process discussed above with reference to FIG. 11B.

In an embodiment of the present inventive concepts, the second buffer layer BFL2 may remain in the indent region IDT and may also partially remain on a bottom RSb of the second recess RS2. The second buffer layer BFL2 on the bottom RSb of the second recess RS2 may have a thickness less than that of the second buffer layer BFL2 in the indent region IDT.

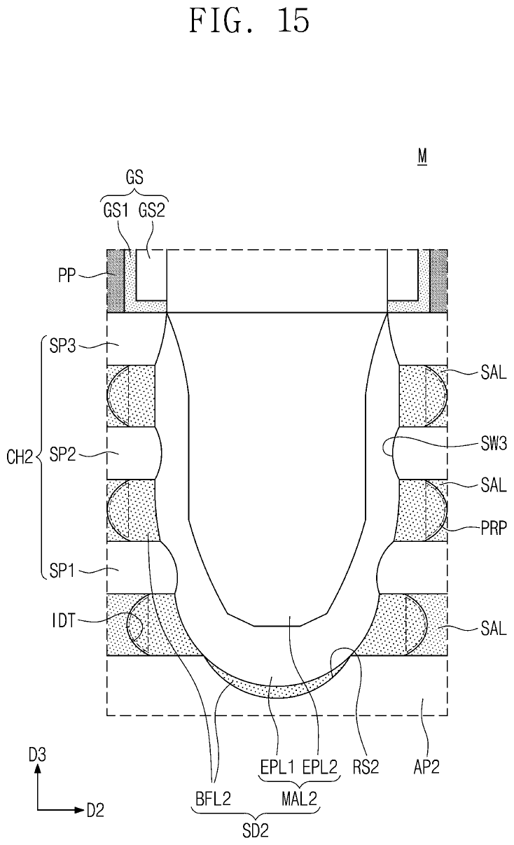

Referring to FIG. 15, a fourth SEG process may be performed in which the first, second, and third semiconductor patterns SP1, SP2, and SP3 and the second buffer layer BFL2 may be used as a seed layer to partially form a first epitaxial layer EPL1 in the second recess RS2. The first epitaxial layer EPL1 may be formed to have a U shape in the second recess RS2, and may be connected to the third sidewall SW3 of each of the first, second, and third semiconductor patterns SP1, SP2, and SP3.

In an embodiment, the first epitaxial layer EPL1 may be formed of or include silicon (Si). The first epitaxial layer EPL1 may be doped with n-type impurities (e.g., at least one selected from phosphorus, arsenic, and antimony). For example, the first epitaxial layer EPL1 may include arsenic (As) as impurities. The first epitaxial layer EPL1 may have an impurity concentration of about 0.1 at % to about 4 at %.

A fifth SEG process may be performed in which the first epitaxial layer EPL1 may be used as a seed layer to form a second epitaxial layer EPL2 on the first epitaxial layer EPL1. The second epitaxial layer EPL2 may be formed to completely fill the second recess RS2.

The second epitaxial layer EPL2 may include impurities (e.g., phosphorus) whose concentration is relatively high. For example, the second epitaxial layer EPL2 may be doped to have an impurity concentration of about 4 at % to about 12 at %. In an embodiment, the impurities may be in-situ implanted during the fifth SEG process. In another embodiment, after the formation of the second epitaxial layer EPL2, an ion implantation process may be performed to dope the second epitaxial layer EPL2 with impurities.

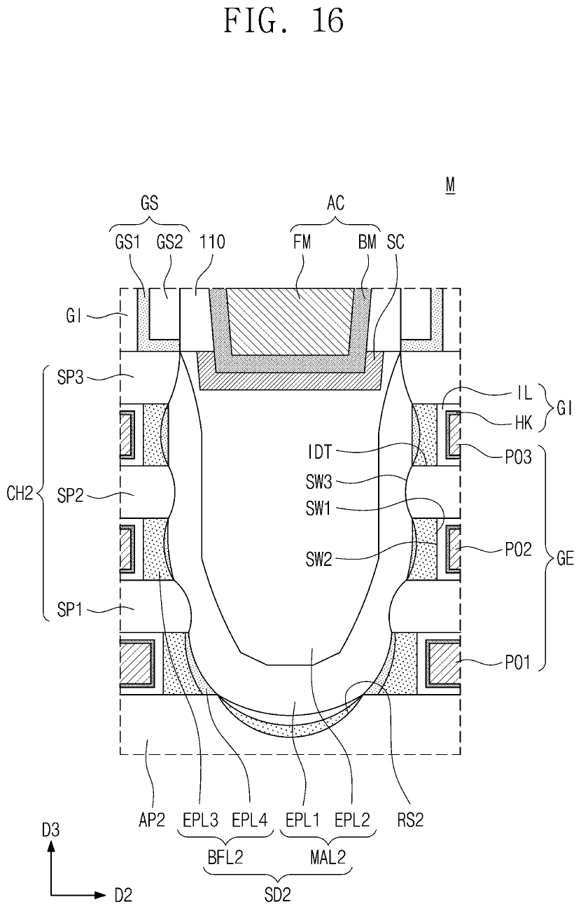

FIG. 16 illustrates an enlarged view showing an example of section M depicted in FIG. 5B. In the embodiment that follows, a detailed description of technical features repetitive to those discussed above with reference to FIG. 6A will be omitted, and a difference thereof will be discussed in detail.

Referring to FIG. 16, the second buffer layer BFL2 may include a third epitaxial layer EPL3 and a fourth epitaxial layer EPL4. The third epitaxial layer EPL3 may be substantially the same as the second buffer layer BFL2 discussed above with reference to FIG. 6A. For example, the third epitaxial layer EPL3 may be formed of or include undoped silicon (Si).

The fourth epitaxial layer EPL4 may be interposed between the third epitaxial layer EPL3 and the second main layer MAL2. In an embodiment, the fourth epitaxial layer EPL4 may be formed of or include carbon-doped silicon (Si:C). The fourth epitaxial layer EPL4 may have a carbon concentration of about 0.1 at % to about 0.5 at %. For example, the fourth epitaxial layer EPL4 may have a carbon concentration of 0.1 at % to 0.5 at %.

The fourth epitaxial layer EPL4 may cause the second buffer layer BFL2 to have an increased resistance to etching. During the removal of the sacrificial layers SAL discussed above with reference to FIG. 11B, the fourth epitaxial layer EPL4 may effectively prevent introduction of an etching material into the second main layer MAL2. In addition, the fourth epitaxial layer EPL4 may effectively prevent a leakage current between the second main layer MAL2 and the first, second, and third inner electrodes PO1, PO2, and PO4.

In a semiconductor device according to the present inventive concepts, as a buffer layer of a source/drain pattern is locally present only in an indent region, it may be possible to reduce a channel resistance and to effectively prevent a leakage current. There may be an increase in volume fraction of a main layer in the source/drain pattern, and thus transistor electrical properties may be improved.

Although some embodiments of inventive concepts have been discussed with reference to accompanying figures, it will be understood that various changes in form and details may be made therein without departing from the spirit and scope of inventive concepts. It therefore will be understood that the embodiments described above are just illustrative but not limiting in all aspects.

1. A semiconductor device, comprising:
a substrate that includes an active pattern;
a channel pattern and a source/drain pattern on the active pattern, wherein the channel pattern includes a plurality of semiconductor patterns that are vertically stacked and spaced apart from each other, the plurality of semiconductor patterns including a first semiconductor pattern and a second semiconductor pattern neighboring the first semiconductor pattern; and
a gate electrode on the plurality of semiconductor patterns,
wherein the gate electrode includes an inner electrode between the first semiconductor pattern and the second semiconductor pattern,
wherein the source/drain pattern includes a buffer layer and a main layer on the buffer layer,
wherein an indent region is defined in a vertical cross section of the semiconductor device by the main layer, the first semiconductor pattern, the second semiconductor pattern, and the inner electrode,
wherein the buffer layer is in the indent region, and
wherein the buffer layer does not extend onto sidewalls of the first semiconductor pattern and the second semiconductor pattern.

2. The semiconductor device of claim 1, wherein the sidewalls of the first semiconductor pattern and the second semiconductor pattern are in contact with the main layer.

3. The semiconductor device of claim 1, wherein
the buffer layer has a first sidewall that faces the inner electrode,
the first semiconductor pattern has a second sidewall in contact with the main layer, and
a curvature of the first sidewall is less than a curvature of the second sidewall.

4. The semiconductor device of claim 1, further comprising a gate dielectric layer between the inner electrode and the source/drain pattern,
wherein the gate dielectric layer has a first sidewall in contact with the buffer layer,
wherein the first semiconductor pattern has a second sidewall in contact with the main layer, and
wherein a curvature of the first sidewall is less than a curvature of the second sidewall.

5. The semiconductor device of claim 4, wherein the gate dielectric layer includes an interfacial layer and a high-k dielectric layer,
wherein the high-k dielectric layer is between the interfacial layer and the inner electrode, and
wherein the interfacial layer is in contact with the buffer layer.

6. The semiconductor device of claim 1, wherein the main layer includes:
a first epitaxial layer in contact with the buffer layer; and
a second epitaxial layer on the first epitaxial layer,
wherein an impurity concentration of the second epitaxial layer is greater than an impurity concentration of the first epitaxial layer.

7. The semiconductor device of claim 1, wherein the main layer includes at least one impurity selected from phosphorus, arsenic, and antimony.

8. The semiconductor device of claim 1, wherein the buffer layer includes a crystalline semiconductor.

9. The semiconductor device of claim 1, wherein the buffer layer includes a first epitaxial layer and a second epitaxial layer, the first epitaxial layer and the second epitaxial layer being in the indent region,
wherein the second epitaxial layer is between the first epitaxial layer and the main layer, and
wherein the second epitaxial layer includes carbon-doped silicon.

10. The semiconductor device of claim 9, wherein a carbon concentration in the second epitaxial layer is in a range of about 0.1 at % to about 0.5 at %.

11. A semiconductor device, comprising:
a substrate including an active pattern;
a channel pattern and a source/drain pattern on the active pattern, wherein the channel pattern includes a plurality of semiconductor patterns vertically stacked and spaced apart from each other, the plurality of semiconductor patterns including a first semiconductor pattern and a second semiconductor pattern neighboring the first semiconductor pattern; and
a gate electrode on the plurality of semiconductor patterns,
wherein the gate electrode includes an inner electrode between the first semiconductor pattern and the second semiconductor pattern,
wherein the source/drain pattern includes a buffer layer and a main layer on the buffer layer,
wherein the buffer layer is between the main layer and the inner electrode,
wherein the buffer layer has a first sidewall that faces the inner electrode,
wherein the first semiconductor pattern has a second sidewall in contact with the main layer, and
wherein a curvature of the first sidewall is less than a curvature of the second sidewall.

12. The semiconductor device of claim 11, further comprising a gate dielectric layer between the inner electrode and the first sidewall of the buffer layer,
wherein the gate dielectric layer has a third sidewall in contact with the first sidewall.

13. The semiconductor device of claim 12, wherein the gate dielectric layer includes an interfacial layer and a high-k dielectric layer,
wherein the high-k dielectric layer is between the interfacial layer and the inner electrode, and
wherein the interfacial layer is in contact with the first sidewall.

14. The semiconductor device of claim 11, wherein the buffer layer includes a crystalline semiconductor.

15. The semiconductor device of claim 11, wherein the main layer includes at least one impurity selected from phosphorus, arsenic, and antimony.

16. A semiconductor device, comprising:
a substrate including an NMOSFET region;
an active pattern on the NMOSFET region;
a channel pattern and a source/drain pattern on the active pattern, wherein the channel pattern includes a plurality of semiconductor patterns stacked and spaced apart from each other, the plurality of semiconductor patterns including a first semiconductor pattern and a second semiconductor pattern neighboring the first semiconductor pattern;
a gate electrode on the channel pattern, wherein the gate electrode includes:
an inner electrode between the first semiconductor pattern and the second semiconductor pattern, and
an outer electrode on an uppermost semiconductor pattern among the plurality of semiconductor patterns;
a gate dielectric layer between the inner electrode and the source/drain pattern;
a gate spacer on a sidewall of the outer electrode;
a gate capping pattern on a top surface of the outer electrode;
an interlayer dielectric layer on the gate capping pattern and the source/drain pattern;
a gate contact that penetrates the interlayer dielectric layer and the gate capping pattern and is electrically connected with the gate electrode;
an active contact that penetrates the interlayer dielectric layer and is electrically connected with the source/drain pattern; and
a first metal layer on the interlayer dielectric layer,
wherein the first metal layer includes a plurality of first wiring lines that are electrically connected to the gate contact and the active contact,
wherein the gate dielectric layer has a first sidewall in contact with the source/drain pattern,
wherein the first semiconductor pattern has a second sidewall in contact with the source/drain pattern, and
wherein a curvature of the first sidewall is less than a curvature of the second sidewall.

17. The semiconductor device of claim 16, wherein the source/drain pattern includes a buffer layer and a main layer on the buffer layer,
wherein the first sidewall of the gate dielectric layer is in contact with the buffer layer, and
wherein the second sidewall of the first semiconductor pattern is in contact with the main layer.

18. The semiconductor device of claim 17, wherein
the buffer layer includes undoped silicon, and
the main layer includes at least one impurity selected from phosphorus, arsenic, and antimony.

19. The semiconductor device of claim 18, wherein the buffer layer further includes carbon-doped silicon.

20. The semiconductor device of claim 16, wherein the gate dielectric layer includes an interfacial layer and a high-k dielectric layer,
wherein the high-k dielectric layer is between the interfacial layer and the inner electrode, and
wherein the interfacial layer is in contact with the source/drain pattern.

21. (canceled)
